(19) United States
(12) Patent Application Publication
(10) Pub. No.: US 2026/0188971 A1
(43) Pub. Date: Jul. 2, 2026

(54) DISTANCE MEASURING DEVICE

(71) Applicant: SONY SEMICONDUCTOR SOLUTIONS CORPORATION, Kanagawa (JP)

(72) Inventors: Yuya MAEDA, Kanagawa (JP); Yohtaro YASU, Kanagawa (JP); Haruhiko TERADA, Kanagawa (JP); Yoshiki EBIKO, Kanagawa (JP)

(73) Assignee: SONY SEMICONDUCTOR SOLUTIONS CORPORATION, Kanagawa (JP)

(21) Appl. No.: 19/130,224

(22) PCT Filed: Nov. 6, 2023
(86) PCT No.: PCT/JP2023/039806

§ 371 Date: May 15, 2025

(30) Foreign Application Priority Data
Nov. 30, 2022 (JP) 2022-192058

(51) Int. Cl. H01S 5/042; G01S 7/481; H01S 5/026

(52) U.S. Cl. CPC H01S 5/042; G01S 7/4814; H01S 5/026

(57) ABSTRACT

A distance measuring device includes a first section including a first optical waveguide configured to convey a chirp signal, a light source that generates light for modulation by a modulator to generate the chirp signal, and a second section including logic circuitry that controls the light source. The first section and the second section are stacked. The distance measuring device further includes a first conductor that forms at least part of an electrical connection between the logic circuitry and the light source, and the first conductor penetrates the first section at a position that is spaced apart from the light source in a first direction.

### CROSS REFERENCE TO RELATED APPLICATIONS

This application claims the benefit of Japanese Priority Patent Application JP 2022-192058 filed on Nov. 30, 2022, the entire contents of each which are incorporated herein by reference.

### TECHNICAL FIELD

The present disclosure relates to a distance measuring device.

### BACKGROUND ART

There has been developed a light detection and ranging (LiDAR) system using a photonic integration circuit (PIC) in which in place of an optical fiber, an optical component such as a silicon (Si) waveguide is stacked on a silicon-on-insulator (SOI) substrate (for example, refer to PTL 1).

### CITATION LIST

### Patent Literature

PTL 1: Japanese Unexamined Patent Application Publication No. 2019-121691

### SUMMARY

### Technical Problem

In such a system, operation becomes unstable due to, for example, heat generation in a laser that is a light source. It is therefore desirable to provide a distance measuring device that makes it possible to suppress instability of operation caused by heat generation or the like.

### Solution to Problem

According to at least one embodiment, a distance measuring device includes a first section including a first optical waveguide configured to convey a chirp signal, a light source that generates light for modulation by a modulator to generate the chirp signal, and a second section including logic circuitry that controls the light source. The first section and the second section are stacked. The distance measuring device further includes a first conductor that forms at least part of an electrical connection between the logic circuitry and the light source, and the first conductor penetrates the first section at a position that is spaced apart from the light source in a first direction. The first conductor penetrates through the first section. The first conductor penetrates through at least part of the second section. The second section includes a silicon layer and an interlayer insulating film. The first conductor penetrates through the interlayer insulating film to the silicon layer. The first conductor electrically connects to a wiring of the interlayer insulating film. The wiring is at a bonding surface between the first section and the second section. The wiring is between a first surface of the interlayer insulating film and a second surface of the interlayer insulating film opposite the first surface. The distance measuring device further includes at least one second conductor that electrically connects the first conductor to the light source. The first section includes at least part of the at least one second conductor. At least part of the at least one second conductor extends in the first direction. The at least one second conductor includes a conductive bump. The distance measuring device further includes a third section that includes the light source, and the first section is between the second section and the third section. The third section includes at least part of the at least one second conductor. The first conductor penetrates through the third section, the first section, and at least part of the second section.

According to at least one embodiment, a distance measuring device includes a first section including a first silicon layer, the first silicon layer including a first optical waveguide configured to convey an optical signal, a light source that generates light for modulation by a modulator to generate the optical signal, a second section including a second silicon layer, the second silicon layer including logic circuitry that controls the light source. The first section and the second section are stacked. The distance measure device further includes a first conductor that forms at least part of an electrical connection between the logic circuitry and the light source. The first conductor penetrates the first section at a position that is spaced apart from the light source in a first direction. The light source is positioned between the first optical waveguide and the first conductor. The first section further includes a splitter configured to split the optical signal into a transmission signal and a reference signal, and a coupler and detector circuitry configured to output a beat signal based on the reference signal and a reflected signal. The logic circuitry includes a controller configured to output an electronic control signal that controls generation of the optical signal.

According to at least one embodiment, a distance measuring device includes a first section including a first optical waveguide configured to convey a chirp signal, a light source that generates light for modulation by a modulator to generate the chirp signal, a second section including logic circuitry that controls the light source. The first section and the second section are stacked. The distance measuring device includes a first conductor that forms at least part of an electrical connection between the logic circuitry and the light source, where the first conductor penetrates the first section at a position that is spaced apart from the light source in a first direction. The distance measuring device further includes at least one second conductor that forms a remaining part of the electrical connection between the logic circuitry and the light source, where at least part of the at least one second conductor extends in the first direction.

### BRIEF DESCRIPTION OF DRAWINGS

FIG. 1 is a diagram illustrating an exemplary schematic configuration of a distance measuring device according to a first embodiment of the present disclosure.

FIG. 2 is a diagram illustrating an exemplary planar configuration of the distance measuring device in FIG. 1.

FIG. 3 is a diagram illustrating an exemplary cross-sectional configuration taken along a line A-A in FIG. 2.

FIG. 4 is a diagram illustrating an exemplary cross-sectional configuration taken along a line B-B in FIG. 2.

FIG. 5 is a diagram illustrating an exemplary cross-sectional configuration taken along a line C-C in FIG. 2.

FIG. 6 is a diagram illustrating an exemplary schematic configuration of an antenna in FIG. 1.

FIG. 7 is a diagram illustrating an exemplary cross-sectional configuration taken along an line A-A in FIG. 6.

FIG. 8 is a diagram illustrating an exemplary cross-sectional configuration taken along a line B-B in FIG. 6.

FIG. 9 is a diagram illustrating an exemplary schematic configuration of a detector in FIG. 1.

FIG. 10 is a diagram illustrating an exemplary perspective configuration of the detector in FIG. 9.

FIG. 11 is a cross-sectional view for describing a method of manufacturing the distance measuring device in FIG. 1.

FIG. 12 is a cross-sectional view for describing a manufacturing method subsequent to FIG. 11.

FIG. 13 is a cross-sectional view for describing a manufacturing method subsequent to FIG. 12.

FIG. 14 is a cross-sectional view for describing a manufacturing method subsequent to FIG. 13.

FIG. 15 is a cross-sectional view for describing a manufacturing method subsequent to FIG. 14.

FIG. 16 is a cross-sectional view for describing a manufacturing method subsequent to FIG. 15.

FIG. 17 is a cross-sectional view for describing a manufacturing method subsequent to FIG. 16.

FIG. 18 is a cross-sectional view for describing a manufacturing method subsequent to FIG. 16.

FIG. 19 is a cross-sectional view for describing a manufacturing method subsequent to FIG. 17.

FIG. 20 is a cross-sectional view for describing a manufacturing method subsequent to FIG. 18.

FIG. 21 is a diagram illustrating a modification example of the cross-sectional configuration in FIG. 5.

FIG. 22 is a diagram illustrating a modification example of the cross-sectional configuration in FIG. 4.

FIG. 23 is a diagram illustrating a modification example of the planar configuration in FIG. 2.

FIG. 24 is a diagram illustrating an exemplary cross-sectional configuration taken along a line A-A in FIG. 23.

FIG. 25 is a diagram illustrating an exemplary schematic configuration of a distance measuring device according to a second embodiment of the present disclosure.

FIG. 26 is a diagram illustrating an exemplary planar configuration of the distance measuring device in FIG. 25.

FIG. 27 is a diagram illustrating an exemplary cross-sectional configuration taken along a line A-A in FIG. 26.

FIG. 28 is a diagram illustrating an exemplary cross-sectional configuration taken along a line B-B in FIG. 26.

FIG. 29 is a diagram illustrating an exemplary cross-sectional configuration taken along a line C-C in FIG. 26.

FIG. 30 is a diagram illustrating a modification example of the cross-sectional configuration in FIG. 29.

FIG. 31 is a diagram illustrating a modification example of the cross-sectional configuration in FIG. 28.

FIG. 32 is a diagram illustrating a modification example of the cross-sectional configuration in FIG. 28.

FIG. 33 is a diagram illustrating an example of a layout of a groove section in FIG. 32.

FIG. 34 is a diagram illustrating an example of the layout of the groove section in FIG. 32.

FIG. 35 is a diagram illustrating an example of the layout of the groove section in FIG. 32.

FIG. 36 is a diagram illustrating a modification example of the cross-sectional configuration in FIG. 31.

FIG. 37 is a diagram illustrating a modification example of the cross-sectional configuration in FIG. 32.

FIG. 38 is a diagram illustrating a modification example of the cross-sectional configuration in FIG. 28.

FIG. 39 is a diagram illustrating a modification example of the cross-sectional configuration in FIG. 29.

FIG. 40 is a diagram illustrating a modification example of the cross-sectional configuration in FIG. 28.

FIG. 41 is a diagram illustrating a modification example of the cross-sectional configuration in FIG. 29.

FIG. 42 is a diagram illustrating an example in which a groove section is provided in a recessed section in FIGS. 38 to 41.

FIG. 43 is a diagram illustrating an example in which the groove section is provided in the recessed section in FIGS. 38 to 41.

FIG. 44 is a diagram illustrating an example in which the groove section is provided in the recessed section in FIGS. 38 to 41.

FIG. 45 is a diagram illustrating a modification example of the cross-sectional configuration in FIG. 28.

FIG. 46 is a diagram illustrating a modification example of the cross-sectional configuration in FIG. 29.

FIG. 47 is a diagram illustrating a modification example of the cross-sectional configuration in FIG. 46.

FIG. 48 is a diagram illustrating a modification example of a planar configuration of a recessed section in FIG. 26.

FIG. 49 is a diagram illustrating a modification example of a cross-sectional configuration of a recessed section in FIG. 28.

FIG. 50 is a diagram illustrating a modification example of a planar configuration of the recessed section and a laser chip in FIG. 26.

FIG. 51 is a diagram illustrating a modification example of the cross-sectional configuration of the recessed section in FIG. 28.

FIG. 52 is a diagram illustrating a modification example of the planar configuration of the recessed section in FIG. 26.

FIG. 53 is a diagram illustrating an exemplary cross-sectional configuration taken along a line A-A in FIG. 52.

FIG. 54 shows diagrams illustrating an exemplary planar configuration of the recessed section and the laser chip in FIG. 53 and an exemplary configuration of a bottom surface of the laser chip in FIG. 53.

FIG. 55 is a diagram illustrating a modification example of the cross-sectional configuration of the recessed section in FIG. 28.

FIG. 56 is a diagram illustrating a modification example of a cross-sectional configuration of a first die in FIG. 28.

FIG. 57 is a diagram illustrating a modification example of the cross-sectional configuration of the first die in FIG. 28.

FIG. 58 is a diagram illustrating a modification example of the cross-sectional configuration of the first die in FIG. 28.

FIG. 59 is a block diagram depicting an example of schematic configuration of a vehicle control system.

FIG. 60 is a diagram of assistance in explaining an example of installation positions of an outside-vehicle information detecting section and an imaging section.

### DESCRIPTION OF EMBODIMENTS

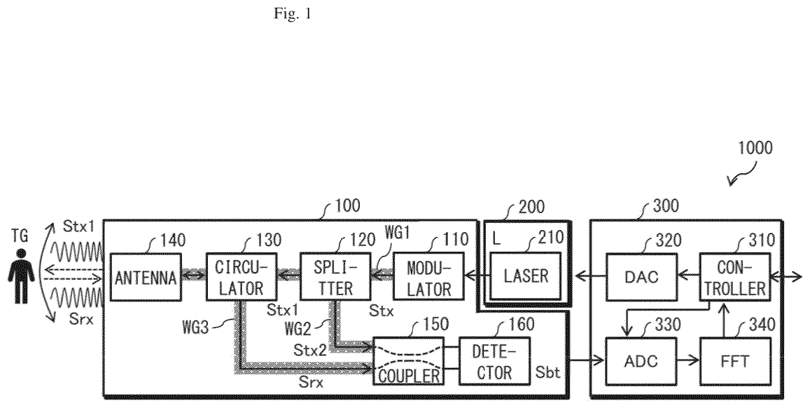

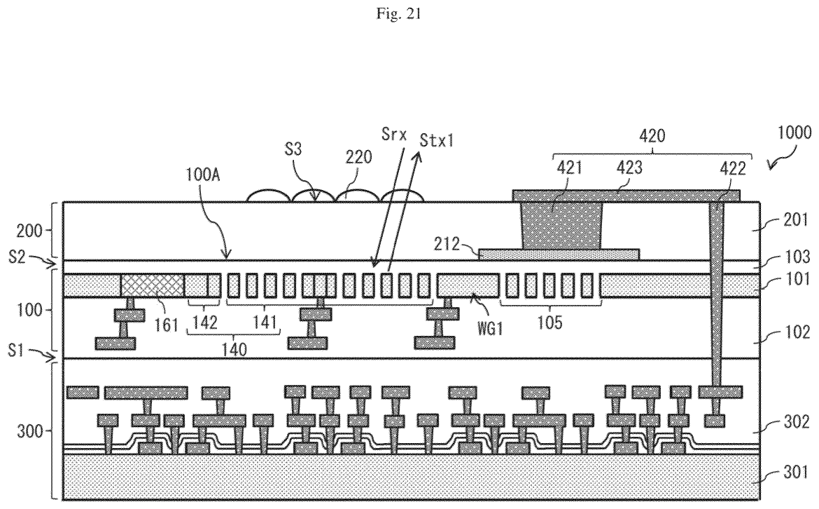

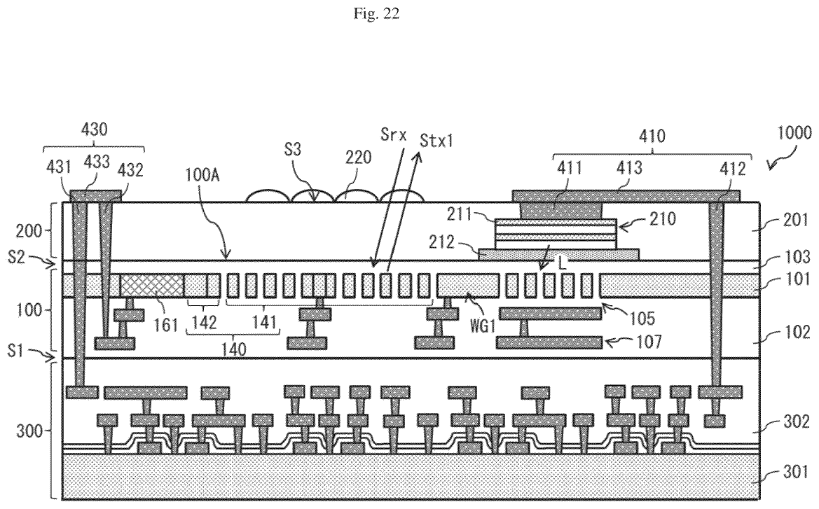

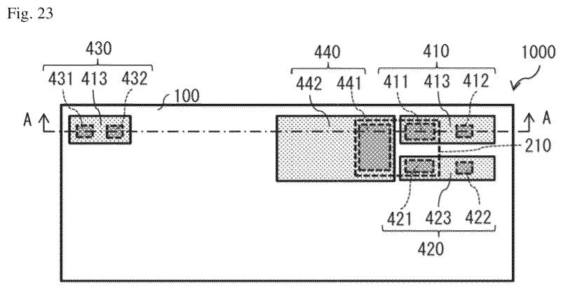

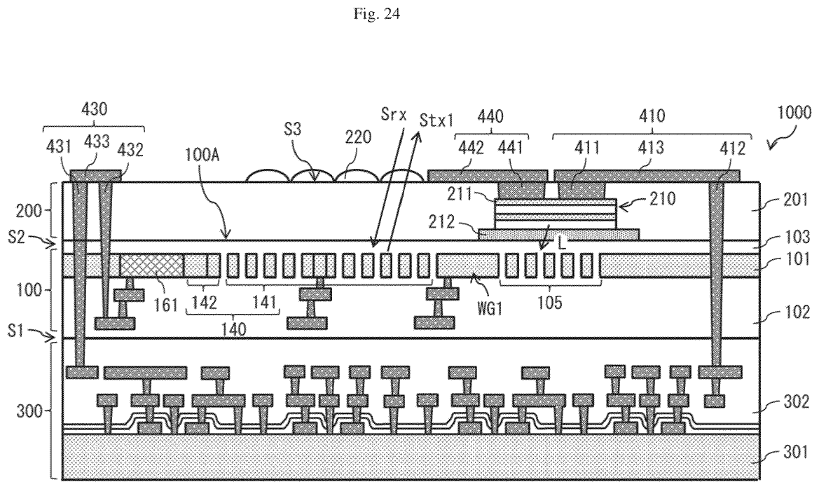

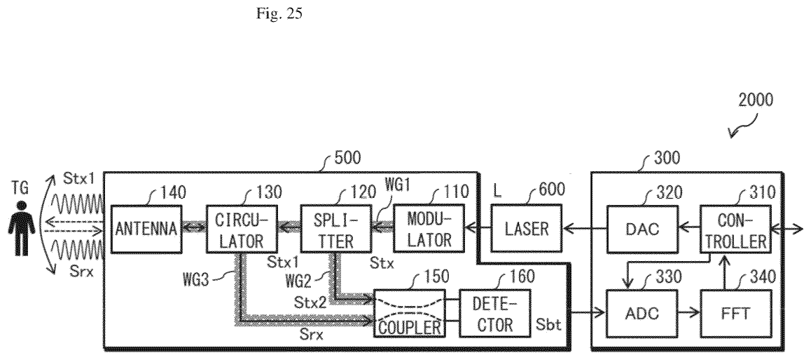

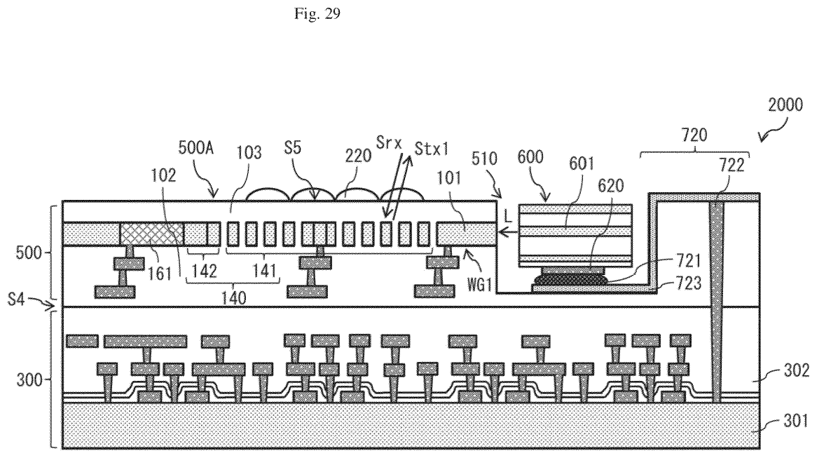

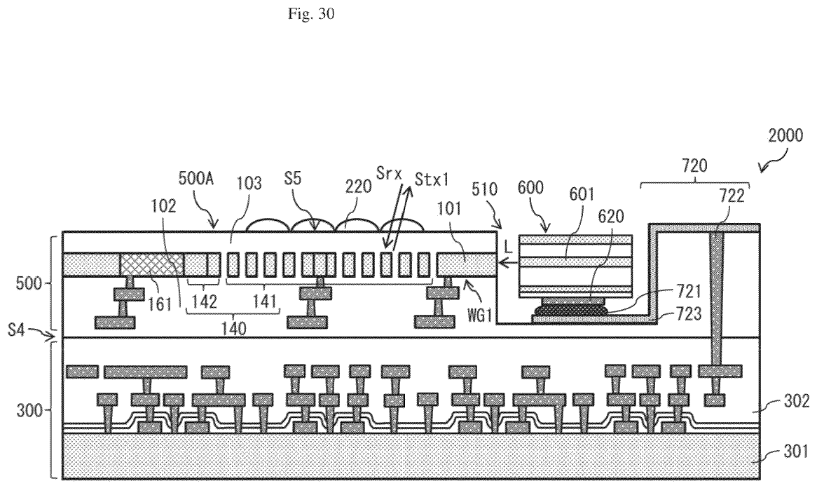

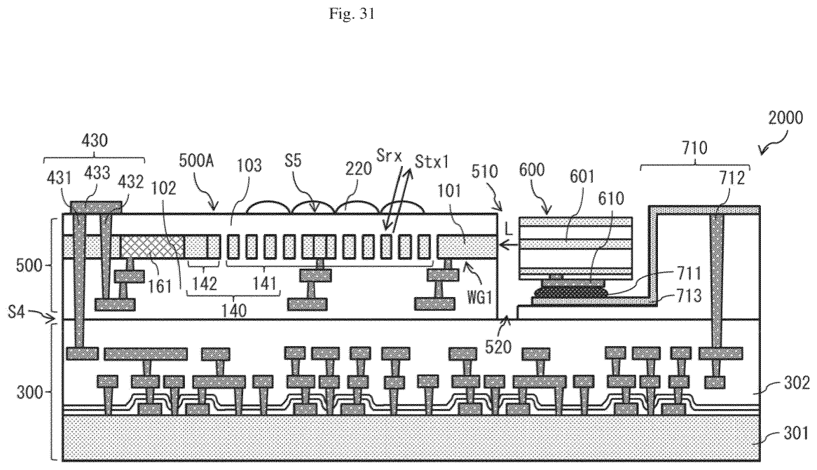

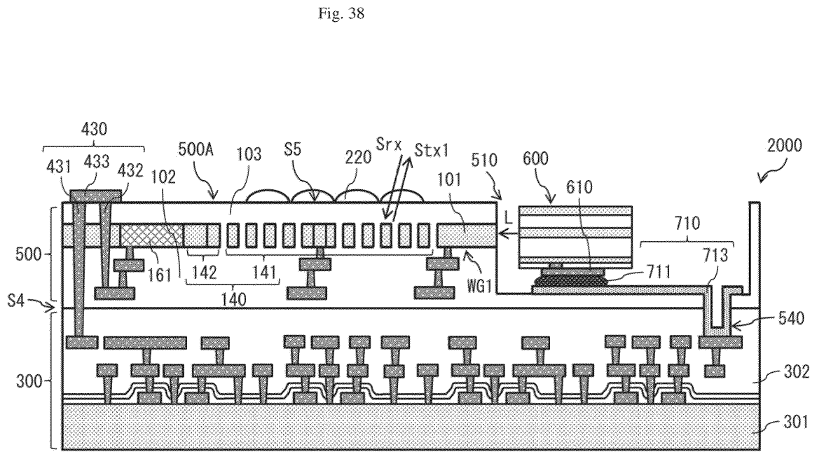

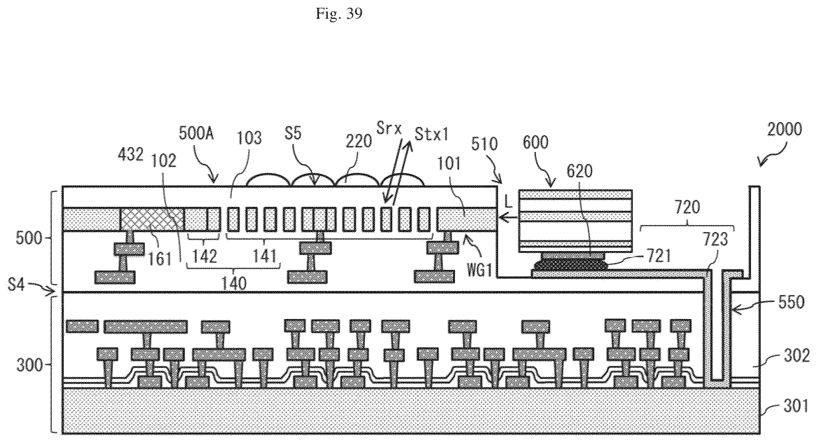

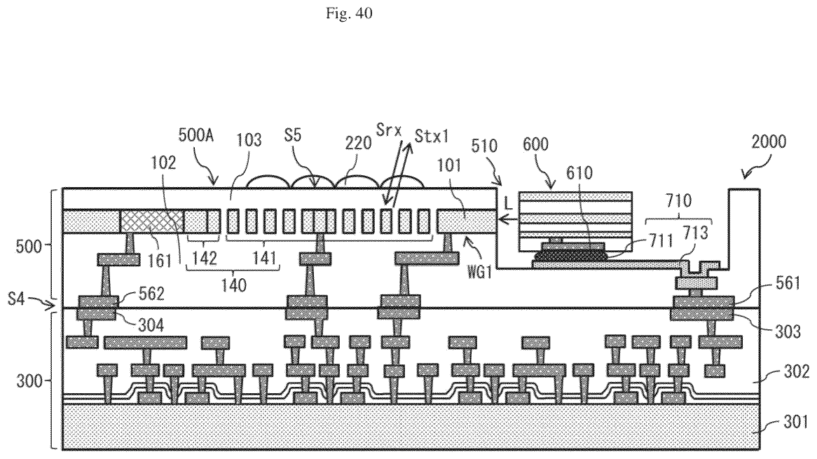

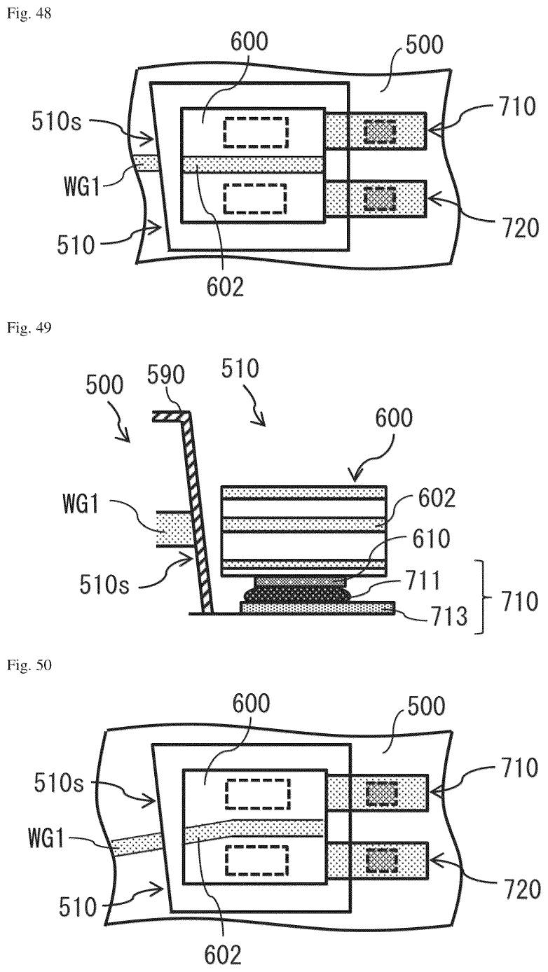

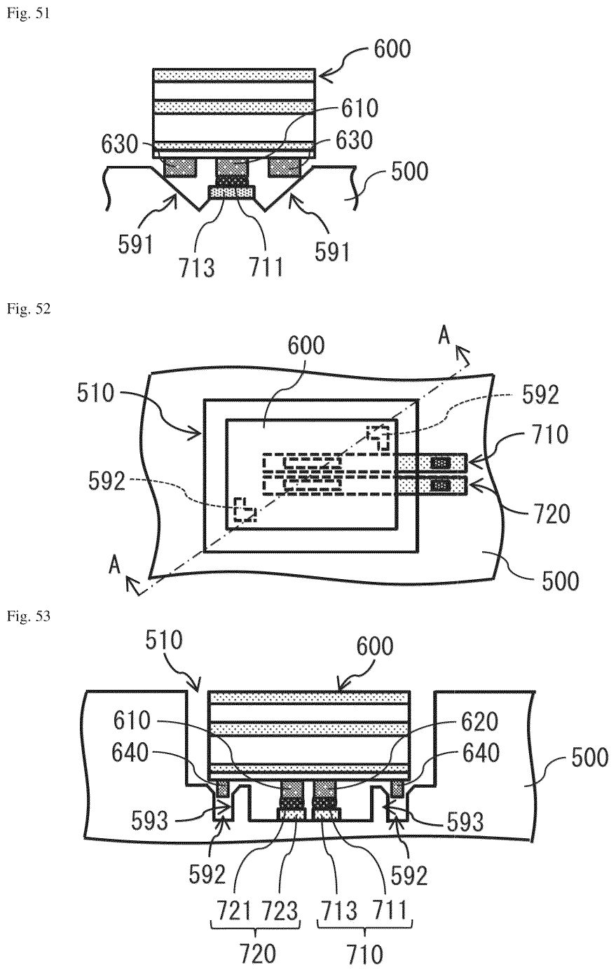

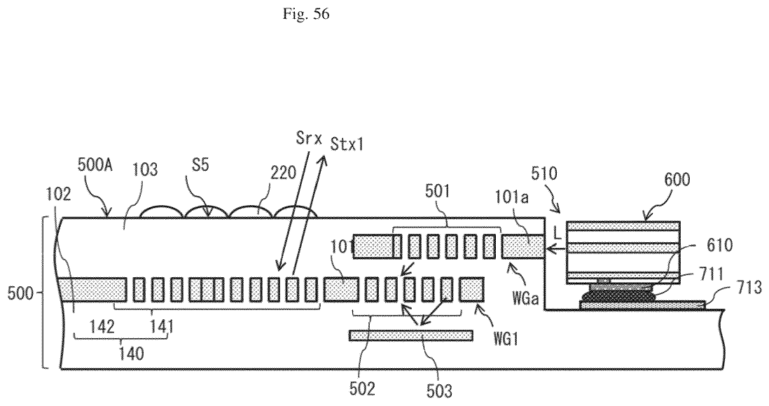

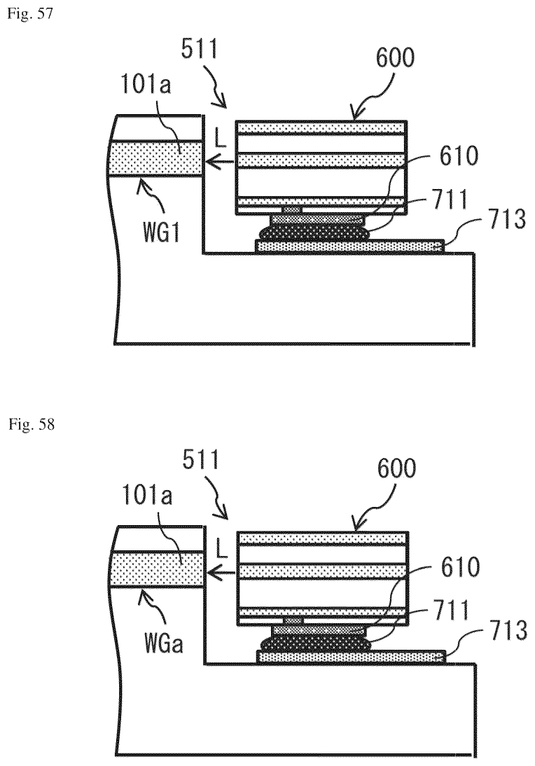

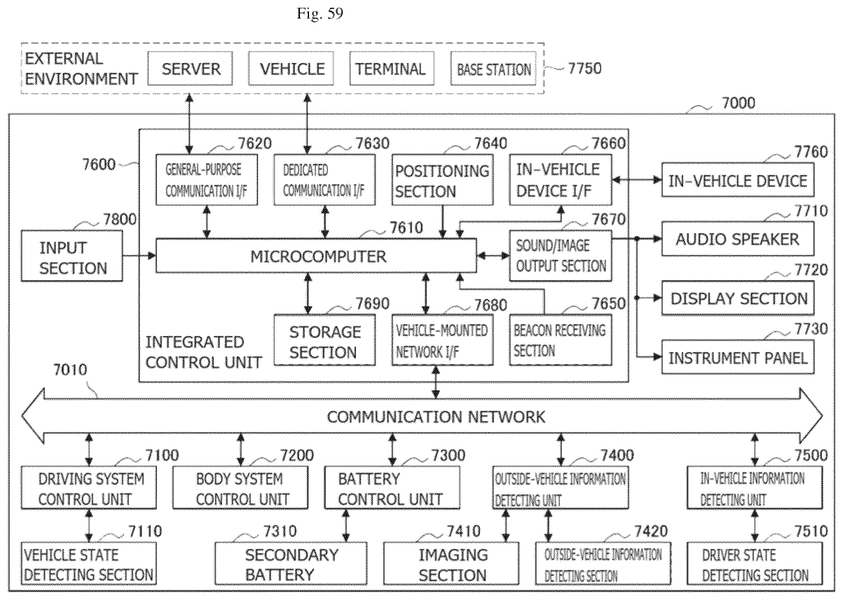

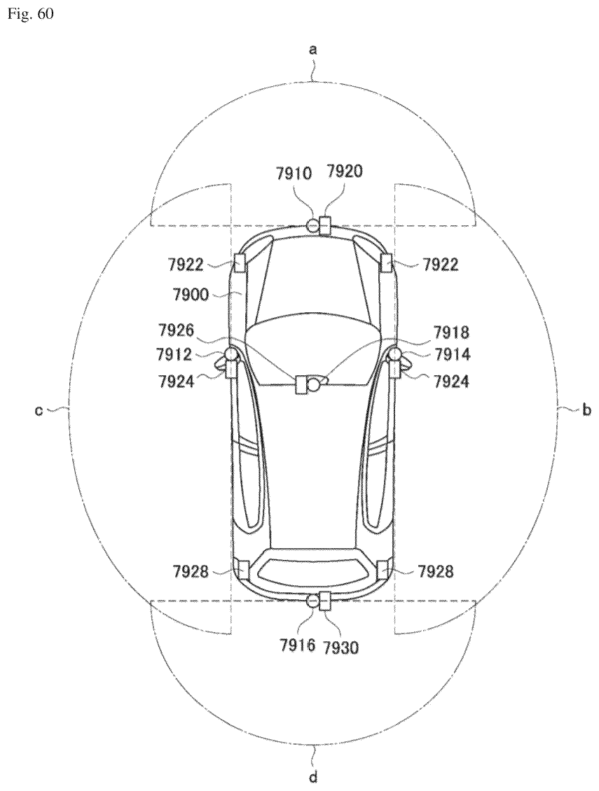

In the following, some embodiments of the present disclosure are described in detail with reference to the drawings. It is to be noted that description is given in the following order.
1. First Embodiment (FIGS. 1 to 20)
An example in which a laser substrate, a PIC substrate, and a signal processing substrate are stacked by through-chip via (TCV) coupling
2. Modification Examples of First Embodiment
Modification Example 2-1: An example in which an anode and a cathode of a laser diode are coupled to a metal wiring line of the signal processing substrate (FIG. 21)
Modification Example 2-2: An example in which a heat dissipation structure is provided directly below the laser diode (FIG. 22)
Modification Example 2-3: An example in which the heat dissipation structure is provided directly above the laser diode (FIGS. 23 and 24)
3. Second Embodiment (FIGS. 25 to 29)
An example in which a laser chip is mounted on a PIC substrate
4. Modification Examples of Second Embodiment
Modification Example 4-1: An example in which an anode and a cathode of the laser chip are coupled to a metal wiring line of a signal processing substrate (FIG. 30)
Modification Example 4-2: An example in which a groove section is provided on a bottom surface of a recessed section of the PIC substrate (FIGS. 31 to 37)
Modification Example 4-3: An example in which a via is provided to the recessed section of the PIC substrate (FIGS. 38 and 39)
Modification Example 4-4: An example in which the PIC substrate and the signal processing substrate are stacked by Cu—Cu coupling (FIGS. 40 to 44)
Modification Example 4-5: An example in which the signal processing substrate and the PIC substrate are coupled to each other by wire bonding (FIGS. 45 to 47)
Modification Example 4-6: An example in which measures against return light is provided to a light incident surface of the recessed section of the PIC substrate or a light-emitting end surface of the laser chip (FIGS. 48 to 50)
Modification Example 4-7: An example in which an alignment structure is provided to a bottom surface of the recessed section of the PIC substrate (FIGS. 51 to 54)
Modification Example 4-8: An example in which a laser chip height adjustment member is provided to the bottom surface of the recessed section of the PIC substrate (FIG. 55)
Modification Example 4-9: An example in which a dedicated waveguide for capturing laser light is provided to the PIC substrate (FIG. 56)
Modification Example 4-10: An example in which a cutout section is provided to the PIC substrate (FIGS. 57 and 58)
5. Application Example (FIGS. 59 and 60)

### 1. First Embodiment

### Configuration

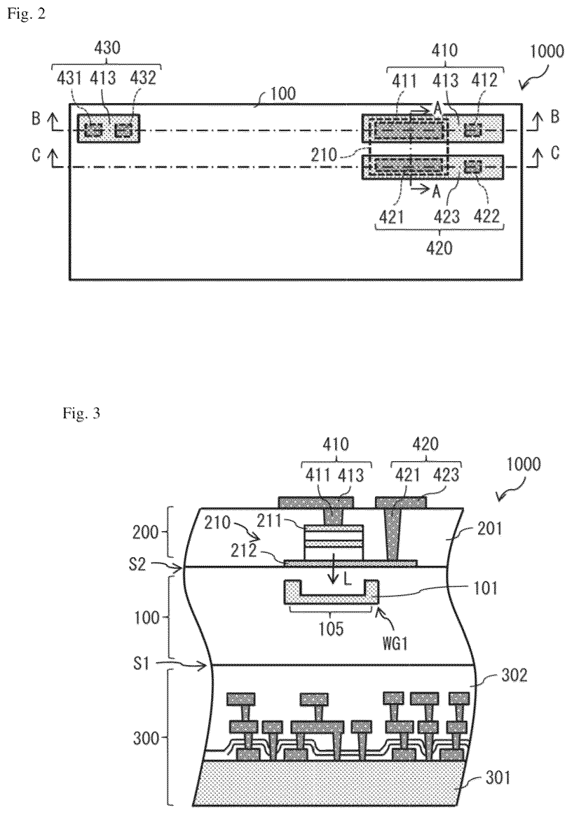

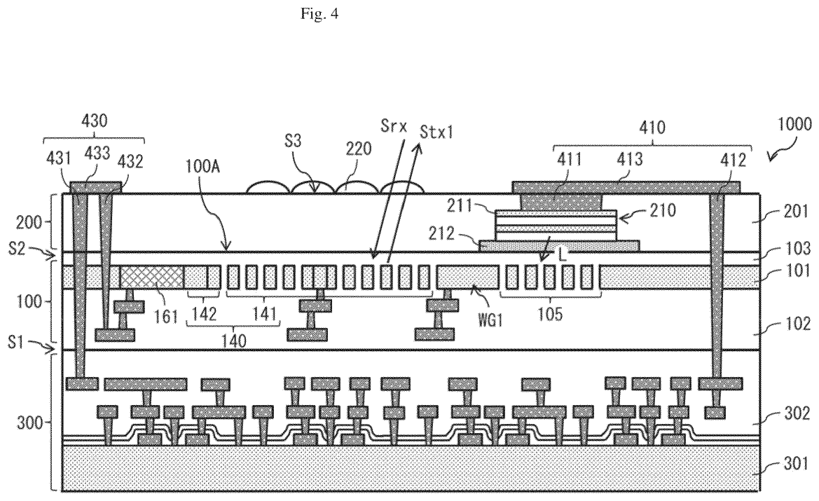

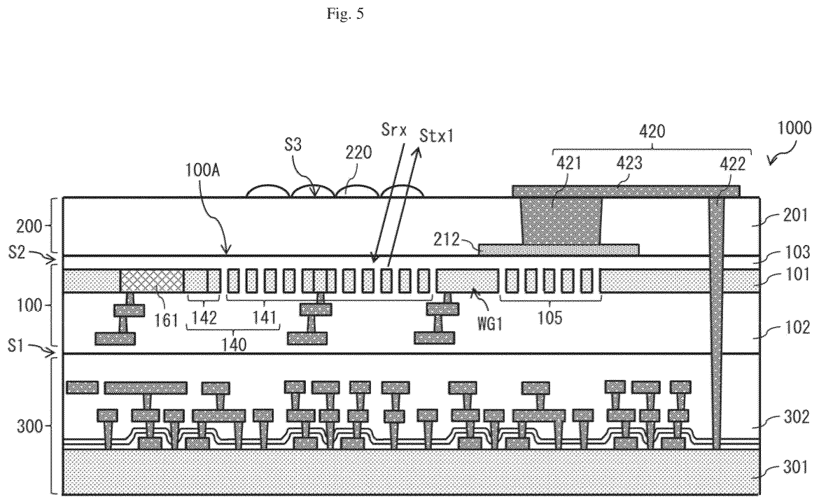

FIG. 1 illustrates an exemplary schematic configuration of a distance measuring device 1000 according to a first embodiment of the present disclosure. FIG. 2 illustrates an exemplary planar configuration of the distance measuring device 1000. FIG. 3 illustrates an exemplary cross-sectional configuration taken along a line A-A in FIG. 2. FIG. 4 illustrates an exemplary cross-sectional configuration taken along a line B-B in FIG. 2. FIG. 5 illustrates an exemplary cross-sectional configuration taken along a line C-C in FIG. 2.

The distance measuring device 1000 includes a frequency modulated continuous wave (FMCW) LiDAR. In the FMCW LiDAR, laser light (transmission signal) of which a frequency has been modulated to be linearly increased with the lapse of time is continuously applied to determine a distance by a frequency difference between the transmission signal and reflected light (return signal).

The distance measuring device 1000 includes, for example, a first die 100, a second die 200, and a third die 300, as illustrated in FIG. 1. The first die 100 and the second die 200 are stacked on the third die 300, and are coupled to each other through a joining surface S1 between the first die 100 and the third die 300 and a joining surface S2 between the second die 200 and the third die 300. A top surface of the second die 200 serves as an entrance/exit surface S3. The first, second, and third dies 100, 200, 300 may form all or part of respective sections herein (e.g., each die corresponds to one of a first, second, or third section herein). The joining surfaces S1 and S2 may also be referred to as bonding surfaces.

### (Second Die 200)

The second die 200 includes, for example, a laser 210, as illustrated in FIG. 1. In the second die 200, the laser 210 is provided in a semiconductor substrate 201.

The laser 210 is a light source that outputs a light signal. In some examples, the light source generates light for modulation by modulator 110 to generate a chirp signal conveyed or carried by waveguide WG1. The laser 210 is a vertical cavity surface emitting laser (VCSEL), and emits laser light L (light signal) having a predetermined fixed wavelength (e.g., 1550 nm) in accordance with control by a controller 310 to be described later. The surface emitting laser includes, for example, an active layer and a pair of distributed Bragg reflector (DBR) layers. The active layer is sandwiched between the pair of DBR layers in a thickness direction. The surface emitting laser includes, for example, a contact layer 211 and a contact layer 212, as illustrated in FIG. 3. The contact layer 211 is ohmically coupled to one of the DBR layers, and the contact layer 212 is ohmically coupled to the other DBR layer. The surface emitting laser emits the laser light L to the first die 100 (a Si layer 101 to be described later) through the contact layer 212 and the joining surface S2.

The second die 200 includes a wiring line that electrically couples the laser 210 and the third die 300 (signal processing circuit) to each other. The second die 200 includes, as the wiring line described above, for example, a wiring line 410 in contact with the contact layer 211, and a wiring line 420 in contact with the contact layer 212, as illustrated in FIGS. 2 to 5. The wiring lines 410 and 420 correspond to specific examples of a “first wiring line” according to an embodiment of the present disclosure. Of the wiring lines 410 and 420, one wiring line serves as a wiring line of a cathode of the laser 210, and the other wiring line serves as a wiring line of an anode of the laser 210. Hereinafter, the wiring line 410 serves as the wiring line of the cathode of the laser 210, and the wiring line 420 serves as the wiring line of the anode of the laser 210. It is to be noted that, depending on the structure of the laser 210, the wiring line 410 may serve as the wiring line of the anode of the laser 210, and the wiring line 420 may serve as the wiring line of the cathode of the laser 210.

The wiring line 410 includes, for example, a via 411, a via 412, and a wiring layer 413, as illustrated in FIGS. 2 to 4. The wiring line 420 includes, for example, a via 421, a via 422, and a wiring layer 423, as illustrated in FIGS. 2, 3, and 5. The wiring line 410 and the wiring line 420 include, for example, copper (Cu). The second die 200 (laser 210) is electrically coupled to the third die 300 (signal processing circuit) through the wiring lines 410 and 420. The via 412, and similarly located vias or electrical con-nections described with reference to other figures herein, may be referred to as a conductor that forms at least part of an electrical connection between logic circuitry and a light source (e.g., between laser 210 and logic circuitry in the third die 300 that controls the laser 210). Such a conductor at least partially penetrates at least one section (e.g., one or more of die 100, 200, and/or 300). For example, a conductor, such as via 412, penetrates a section (e.g., die 100) that includes the waveguide WG1 (e.g., die 100) at a position that is spaced apart from the laser 210 in a first direction, which is a horizontal direction in FIG. 4 and other figures. Throughout the figures, the wiring lines that connect the conductor to the laser 210 may be referred to as at least one conductor that forms a remaining part of the electrical connection between the logic circuitry that controls the laser 210 and the laser 210. In FIG. 4, these conductors or wiring lines include wiring lines 411 and 413. Even if not explicitly stated below, it should be appreciated that at least FIGS. 5, 19-22, 24, 28-32, 36-41, 46, and 47 illustrate additional examples of the above-mentioned conductor that is spaced apart from the laser 210 and/or the above-mentioned conductor that forms a remaining part of an electrical connection between a light source, such as laser 210, and logic circuitry, such as controller 310, that controls the light source. Such conductor(s) may have heat dissipation qualities/functions described herein.

The via 411 is in contact with the contact layer 211 and the wiring layer 413. The via 411 is provided in the semiconductor substrate 201, and extends in a stacking direction of the semiconductor substrate 201. The via 411 includes, for example, a metal (e.g., Cu) embedded in a via hole provided in the semiconductor substrate 201. The via 412 is in contact with the wiring layer 413, and a wiring layer (e.g., Cu) in an interlayer insulating film 302 to be described later. This wiring layer is electrically coupled to, for example, the controller 310. The via 412 is provided in the first die 100, the second die 200, and the third die 300, and extends from the semiconductor substrate 201 to the interlayer insulating film 302. The via 412 includes, for example, a metal (e.g., Cu) embedded in a via hole provided from the semiconductor substrate 201 to the interlayer insulating film 302. The wiring layer 413 is disposed on a front surface of the semiconductor substrate 201, and is in contact with the via 411 and the via 412. The wiring layer 413 includes a metal (e.g., Cu).

The via 421 is in contact with the contact layer 212 and the wiring layer 423. The via 421 is provided in the semiconductor substrate 201, and extends in the stacking direction of the semiconductor substrate 201. The via 421 includes, for example, a metal (e.g., Cu) embedded in a via hole provided in the semiconductor substrate 201. The via 422 is in contact with the wiring layer 423 and a Si substrate 301. The via 422 is provided in the first die 100, the second die 200, and the third die 300, and extends from the semiconductor substrate 201 to the interlayer insulating film 302. The via 422 includes, for example, a metal (e.g., Cu) embedded in a via hole provided from the semiconductor substrate 201 to the interlayer insulating film 302. The wiring layer 423 is disposed on the front surface of the semiconductor substrate 201, and is in contact with the via 421 and the via 422. The wiring layer 423 includes a metal (e.g., Cu).

The second die 200 and the first die 100 further include, for example, a wiring line 430 that electrically couples a detector 160 to be described later and the third die 300 (signal processing circuit) to each other. The wiring line 430 includes, for example, a via 431, a via 432, and a wiring layer 433, as illustrated in FIGS. 2 and 4. The wiring line 430 includes, for example, Cu. The first die 100 (detector 160) is electrically coupled to the third die 300 (signal processing circuit) through the wiring line 430.

The via 431 is in contact with a wiring layer (e.g., Cu) in the interlayer insulating film 302 and the wiring layer 433. This wiring layer is electrically coupled to, for example, the controller 310. The via 431 extends from the semiconductor substrate 201 to the interlayer insulating film 302. The via 431 includes, for example, a metal (e.g., Cu) embedded in a via hole provided from the semiconductor substrate 201 to the interlayer insulating film 302. The via 432 is in contact with a wiring layer (e.g., Cu) in an interlayer insulating film 102 and the wiring layer 433 that are electrically coupled to the detector 160. The via 432 extends from the semiconductor substrate 201 to the interlayer insulating film 102. The via 432 includes, for example, a metal (e.g., Cu) embedded in a via hole provided from the semiconductor substrate 201 to the interlayer insulating film 102. The wiring layer 433 is disposed on the front surface of the semiconductor substrate 201, and is in contact with the via 431 and the via 432. The wiring layer 433 includes a metal (e.g., Cu).

### (First Die 100)

The first die 100 includes, for example, a modulator 110, a splitter 120, a circulator 130, an antenna 140, a coupler 150, and the detector 160, as illustrated in FIG. 1. In the first die 100, the modulator 110, the splitter 120, the circulator 130, the antenna 140, the coupler 150, and the detector 160 are provided in a PIC substrate 100A.

The PIC substrate 100A includes, for example, the Si layer 101, the interlayer insulating film 102, and a buried oxide (BOX) layer 103, as illustrated in FIGS. 3 to 5. The Si layer 101 is sandwiched between the interlayer insulating film 102 and the BOX layer 103. The PIC substrate 100A is obtained by removing a Si substrate 104 to be described later from an SOI substrate 106 to be described later. The BOX layer 103 includes a SiO₂ layer. The interlayer insulating film 102 is a layer provided on the SOI substrate 106, and has a configuration in which a plurality of patterned wiring layers and a via that couples the wiring layers to each other are provided in a plurality of SiO₂ layers stacked. A front surface of the interlayer insulating film 102 serves as a bottom surface of the first die 100. The front surface of the interlayer insulating film 102 is in contact with a top surface of the third die 300 (interlayer insulating film 302). A front surface of the BOX layer 103 serves as a top surface of the first die 100.

Optical waveguides WG1, WG2, and WG3 are provided in the Si layer 101. The optical waveguide WG1 extends, for example, from a portion directly below the laser 210 to the antenna 140 through the modulator 110, the splitter 120, and the circulator 130. The optical waveguide WG2 is an optical wavelength branching from the optical waveguide WG1 in the splitter 120, and is coupled to one input end (optical waveguide 151 to be described later) of the coupler 150. The optical waveguide WG3 is an optical waveguide branching from the optical waveguide WG1 in the circulator 130, and is coupled to another input end (optical waveguide 152 to be described later) of the coupler 150.

The laser light L emitted from the laser 210 enters the optical waveguide WG1. A diffraction grating 105 is provided at a location opposed to the laser 210 (a portion directly below the laser 210) of the optical waveguide WG1. The diffraction grating 105 is, for example, an element in which a plurality of grooves or through holes is disposed side by side in one line with a pitch of several hundreds of nm in the Si layer 101. The diffraction grating 105 guides the laser light L emitted from the laser 210 into the optical waveguide WG1. The laser light L propagating through the optical waveguide WG1 is inputted to the modulator 110. In other words, the diffraction grating 105 guides the laser light L emitted from the laser 210 to the modulator 110.

The modulator 110 performs frequency modulation of the laser light L in accordance with control by the controller 310. For example, the modulator 110 modulates the laser light L to linearly increase a frequency of the laser light L with a lapse of time, and thereafter modulates the laser light L to linearly decrease the frequency of the laser light L with a lapse of time. For example, the modulator 110 periodically repeats such linear increase and decrease of the frequency to generate a transmission signal Stx, and outputs the transmission signal Stx to the splitter 120 through the optical waveguide WG1. The transmission signal Stx is a chirp signal obtained by performing frequency modulation of the laser light L by the modulator 110. The optical waveguide WG1 transmits the chirp signal. The modulator 110 is provided in the Si layer 101, for example. The modulator 110 includes, for example, a Mach-Zehnder interferometer in which a Si waveguide branches into two. On this occasion, the modulator 110 generates a signal having a changed phase of light by forming a PN junction in one branching waveguide and applying a voltage of an alternating current waveform to the PN junction to change a refractive index by carrier plasma effect. The modulator 110 is able to modulate the phase of an original signal by multiplexing a generated signal waveform and an original waveform at an exit of the interferometer.

The splitter 120 splits the transmission signal Stx into a transmission signal Stx (transmission signal Stx1) for being applied to a target TG, and a transmission signal Stx (transmission signal Stx2) for interfering with a return signal Srx (also called a reflected signal) in the coupler 150. The transmission signal Stx1 has most of energy of the transmission signal Stx. The transmission signal Stx2 is a reference signal having an amount of energy that is much smaller than the energy of the transmission signal Stx1, but sufficient to interfere with the return signal Srx in the coupler 150. The return signal Srx corresponds to a signal having a delayed phase in relation to the transmission signal Stx1. The return signal Srx is generated by reflecting the transmission signal Stx by the target TG.

The splitter 120 is an element having three ports. In the splitter 120, a first port and a third port are present in the optical waveguide WG1. A second port is present in the optical waveguide WG2. The optical waveguide WG2 is disposed in proximity to a portion between the first port and the third port of the optical waveguide WG1. This causes the light signal that propagates through the optical waveguide WG1 to leak into the optical waveguide WG2. The light signal having leaked from the optical waveguide WG1 to the optical waveguide WG2 propagates through the optical waveguide WG2 as the transmission signal Stx2. The optical waveguide WG2 transmits the transmission signal Stx2.

The circulator 130 is an element having three ports. In the circulator 130, the transmission signal Stx1 having entered from a first port is transmitted to a third port, and the return signal Srx having entered from the third port is transmitted to a second port. In the circulator 130, the first port is coupled to the optical waveguide WG1, and the second port is coupled to the optical waveguide WG2. The third port is coupled to an optical waveguide extending from the antenna 140. For example, the circulator 130 serves to rectify a light signal to be transmitted and a light signal received from a Si antenna 141. In the circulator 130, signal intensity of each of a transmission signal and a reception signal is divided into 50% and 50% at each branch by a structure in which an optical waveguide including Si branches. Handling such half signals makes it possible to divide transmission light and reception light.

The antenna 140 is a non-mechanical scanner not having a driving section. The antenna 140 transmits the transmission signal Stx1 to the target TG through a lens 220, and receives the return signal Srx through the lens 220. The lens 220 is bonded to a region (entrance/exit surface S3) opposed to the Si antenna 141 of a front surface of the second die 200. The transmission signal Stx1 is outputted from the entrance/exit surface S3, and the return signal Srx enters the entrance/exit surface S3. The lens 220 is bonded to the entrance/exit surface S3, and the transmission signal Stx is outputted from the antenna 140 to outside through the lens 220 and the entrance/exit surface S3, and the return signal Srx enters the antenna 140 from the outside through the lens 220 and the entrance/exit surface S3.

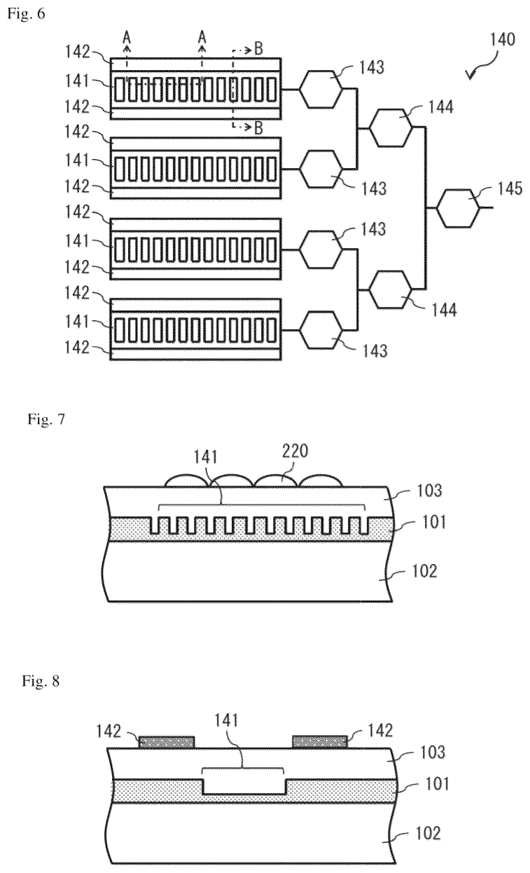

The antenna 140 includes, for example, a plurality (e.g., four) of antenna bodies each including the Si antenna 141 and a pair of heaters 142 provided on both sides of the Si antenna 141, as illustrated in FIG. 6. The antenna bodies each extend in a common direction, and the plurality of antenna bodies are disposed side by side at predetermined intervals in a direction orthogonal to the direction where the antenna bodies extend.

The Si antenna 141 includes a diffraction grating provided in the Si layer 101. The diffraction grating is, for example, an element in which a plurality of grooves or through holes is disposed side by side in one line with a pitch of several hundreds of nm in the Si layer 101. The Si antenna 141 outputs the transmission signal Stx1, which has a peak at a certain location corresponding to the pitch of the diffraction grating, to a front surface of the Si layer 101 at a predetermined angle in accordance with control by the controller 310. The heaters 142 each include a resistor element extending along the Si antenna 141. The heaters 142 each heat the Si antenna 141 by heat generation of the resistor element caused by application of a current to the resistor element in accordance with control by the controller 310. In the Si antenna 141, a refractive index is changed by heating by the heaters 142, and the transmission signal Stx1 is outputted at an angle corresponding to change in the refractive index. In other words, the Si antenna 141 sweeps the transmission signal Stx1 in a predetermined external region in accordance with control by the controller 310.

In a case where the antenna 140 includes four antenna bodies, the antenna 140 further includes, for example, four optical switches 143 that are provided one for each of the antenna bodies, and two optical switches 144 that are provided one for every two optical switches 143, as illustrated in FIG. 6. Each of the optical switches 143 is a switch that connects and disconnects an optical waveguide between two terminals (a first terminal and a second terminal). Each of the optical switches 144 is a switch that connects and disconnects an optical waveguide between two terminals (a third terminal and a fourth terminal). The antenna 140 further includes, for example, one optical switch 145 coupled to the two optical switches 144, as illustrated in FIG. 6. The optical switch 145 is a switch that connects and disconnects an optical waveguide between two terminals (a fifth terminal and a sixth terminal).

In each of the optical switches 143, the first terminal is coupled to the antenna body, and a second terminal is coupled to the second terminal of another optical switch 143 and the third terminal of the optical switch 144. In each of the optical switches 144, the third terminal is coupled to the second terminals of two corresponding optical switches 143, and the fourth terminal is coupled to the fourth terminal of the other optical switch 144 and the fifth terminal of the optical switch 145. In the optical switch 145, the fifth terminal is coupled to the fourth terminals of the two optical switches 144, and the sixth terminal is coupled to the second port of the circulator 130.

The antenna bodies each include, for example, a diffraction grating provided in the Si layer 101, as illustrated in FIGS. 7 and 8. FIG. 7 illustrates an exemplary cross-sectional configuration of the antenna body taken along a line A-A in FIG. 6. FIG. 8 illustrates an exemplary cross-sectional configuration of the antenna body taken along a line B-B in FIG. 6. The diffraction grating is, for example, an element in which a plurality of grooves is disposed side by side in one line with a pitch of several hundreds of nm in the Si layer 101, as illustrated in FIGS. 7 and 8. The depth of each of the grooves is, for example, several hundreds of nm, and the thickness of a portion, corresponding to a base of the diffraction grating, of the Si layer 101 is, for example, several hundreds of nm.

In the Si antenna 141, the transmission signal Stx1 having a peak at a certain location corresponding to the pitch of the diffraction grating is outputted to the front surface of the Si layer 101 at a predetermined angle. The heaters 142 each include a resistor element extending along the Si antenna 141. The heaters 142 each heat the Si antenna 141 by heat generation of the resistor element caused by application of a current to the resistor element in accordance with control by the controller 310. In the Si antenna 141, the refractive index is changed by heating by the heaters 142, and the transmission signal Stx1 is outputted at an angle corresponding to change in the refractive index.

The antenna 140 turns on and off the four optical switches 143, the two optical switches 144, and the one optical switch 145 in accordance with control by the controller 310. Thus, the antenna 140 outputs the transmission signal Stx1 in a predetermined direction from each of the antenna bodies, and receives the return signal Srx inputted from outside.

The coupler 150 is an element that generates a beat signal Sbt by interference between the transmission signal Stx2 and the return signal Srx. The frequency of the beat signal Sbt is changed in accordance with a frequency difference between the transmission signal Stx2 and the return signal Srx. The frequency difference is changed in accordance with a distance from the Si antenna 141 to the target TG. Accordingly, it is possible to estimate the distance from the Si antenna 141 to the target TG on the basis of the frequency of the beat signal Sbt.

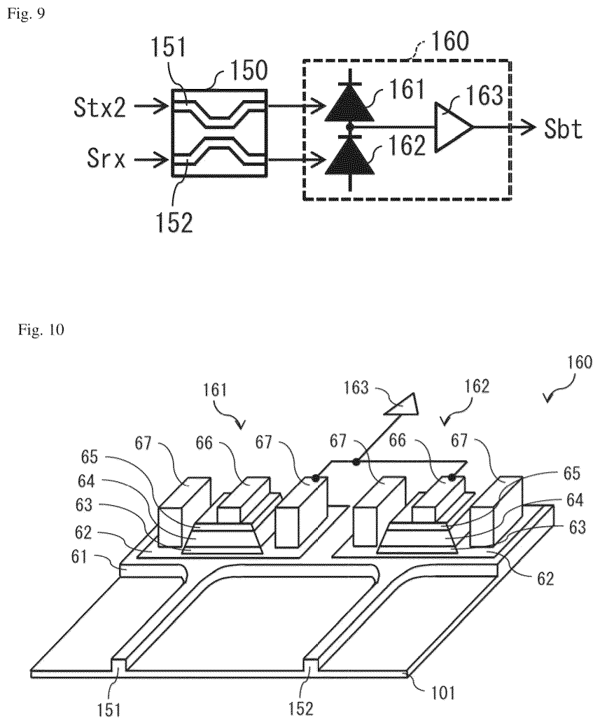

The coupler 150 includes, for example, the optical waveguide 151 for propagating the transmission signal Stx2, and the optical waveguide 152 for propagating the return signal Srx, as illustrated in FIG. 9. Each of the optical waveguides 151 and 152 is, for example, a rib waveguide. A portion of the optical waveguide 151 and a portion of the optical waveguide 152 are disposed in proximity to each other. This causes the transmission signal Stx2 that propagates through the optical waveguide 151 and the return signal Srx that propagates through the optical waveguide 152 to interfere with each other, thereby generating the beat signal Sbt.

The detector 160 is an element that extracts the beat signal Sbt from signals having propagated through the optical waveguides 151 and 152 in accordance with control by the controller 310. A module including the coupler 150 and the detector 160 corresponds to a specific example of a “signal generator that generates a beat signal” according to an embodiment of the present disclosure. The detector 160 includes, for example, Ge-PDs 161 and 162 that are coupled in series to each other, and a transimpedance amplifier 163 that is coupled to a coupling node between the Ge-PD 161 and the Ge-PD 162, as illustrated in FIG. 10.

The Ge-PD 161 is, for example, a PIN photodiode coupled to the optical waveguide 151, as illustrated in FIG. 9. The Ge-PD 162 is, for example, a PIN photodiode coupled to the optical waveguide 152, as illustrated in FIG. 9. The Ge-PDs 161 and 162 each include, for example, a Si terrace section 61 coupled to the optical waveguides 151 and 152, and a p-type Si layer 62. The p-type Si layer 62 is formed by ion-injecting B into the Si terrace section 61. The Si terrace section 61 and the optical waveguides 151 and 152 are provided in the common Si layer 101.

The Ge-PDs 161 and 162 each further include, for example, an island-shaped i-type Ge layer 63, a two-dimensionally grown i-type Ge layer 64, and an n-type Ge layer 65. The island-shaped i-type Ge layer 63 and the two-dimensionally grown i-type Ge layer 64 are provided on the p-type Si layer 62. The n-type Ge layer 65 is formed by ion-injecting P into the two-dimensionally grown i-type Ge layer 64. A stacked body including the p-type Si layer 62, the island-shaped i-type Ge layer 63, the two-dimensionally grown i-type Ge layer 64, and the n-type Ge layer 65 is included in the PIN photodiode. In the PIN photodiode, the island-shaped i-type Ge layer 63 that is ef-fectively of p-type and does not include a depletion layer has a small thickness, and the two-dimensionally grown i-type Ge layer 64 having a large thickness serves as a depletion layer, which improves sensitivity.

The Ge-PDs 161 and 162 each further include, for example, an n-side electrode 66 in contact with the n-type Ge layer65, and a p-side electrode 67 in contact with the p-type Si layer 62. The p-side electrode 67 of the Ge-PD 161 and the n-side electrode 66 of the Ge-PD 162 are coupled to each other by a wiring line, and the wiring line that couples the p-side electrode 67 of the Ge-PD 161 and the n-side electrode 66 of the Ge-PD 162 to each other is coupled to an input end of the transimpedance amplifier 163.

The transimpedance amplifier 163 performs impedance conversion and amplification of a current signal photoelectrically converted by the Ge-PDs 161 and 162, and outputs the beat signal Sbt as a voltage signal.

### (Third Die 300)

The third die 300 includes, for example, the controller 310, a DAC 320, an ADC 330, and a fast Fourier transform (FFT) 340, as illustrated in FIG. 1. The FFT 340 corresponds to a specific example of a “signal processor that processes a beat signal” according to an embodiment of the present disclosure. In some examples, the third die 300 is referred to as including logic circuitry that outputs an electronic signal that controls the laser 210 to generate an optical signal (e.g., a chirp signal). In some cases, the controller 310 corresponds to or forms part of the logic circuitry.

The controller 310 generates, for example, a control signal for controlling the laser 210, the modulator 110, the antenna 140, and the detector 160, and outputs the control signal to the DAC 320. The controller 310 further generates, for example, a control signal for controlling the ADC 330, and outputs the control signal to the ADC 330. The DAC 320 performs DA conversion of the control signal received from the controller 310, and outputs an thus-obtained analog control signal to the laser 210, the modulator 110, the antenna 140, and the detector 160. The ADC 330 performs AD conversion of the beat signal Sbt received from the detector 160, and outputs the beat signal Sbt to the FFT 340. The FFT 340 performs FFT of the beat signal Sbt being digital received from the ADC 330 to obtain power spectrum density, and derives the frequency of the beat signal Sbt on the basis of the obtained power spectrum density. The FFT 340 outputs information (frequency information) about the derived frequency to the controller 310. The controller 310 outputs the frequency information received from the FFT 340 to outside in accordance with control from the outside.

The third die 300 includes, for example, the Si substrate 301, as illustrated in FIGS. 3 to 5. The Si substrate 301 includes, for example, signal processing circuits such as the controller 310, the DAC 320, the ADC 330, and the FFT 340. The interlayer insulating film 302 is provided on the Si substrate 301. The interlayer insulating film 302 has a configuration in which a plurality of patterned wiring layers and a via that couples the wiring layers to each other are provided in a plurality of SiO₂ layers stacked. A wiring line and a via in the signal processing circuits, a wiring line and a via for electrically coupling the signal processing circuits to the first die 100 and the second die 200, and the like are provided in the interlayer insulating film 302.

### Manufacturing Method

Next, description is given of a method of manufacturing the distance measuring device 1000.

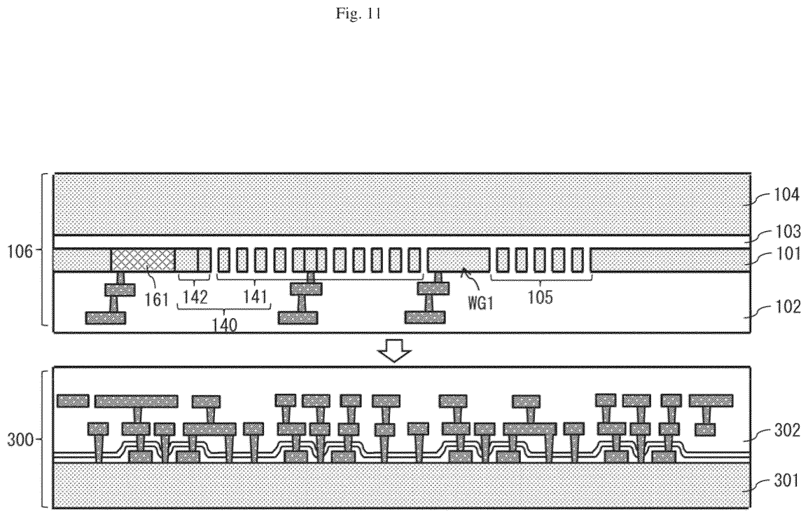

FIGS. 11 to 20 each are a cross-sectional view for describing a process of manufacturing the distance measuring device 1000. First, the SOI substrate 106 is prepared (FIG. 11). The SOI substrate 106 includes a substrate in which the BOX layer 103 and the Si layer 101 are provided on the Si substrate 104 in this order. Next, the optical waveguides WG1, WG2, and WG3, the splitter 120, the circulator 130, the Si antenna 141, the coupler 150, and portions (the Si terrace sections 61 and the p-type Si layers 62) of the Ge-PDs 161 and 1662 are formed in the Si layer 101 of the SOI substrate 106 (FIG. 11). Next, the interlayer insulating film 102 is formed on the SOI substrate 106 (FIG. 11).

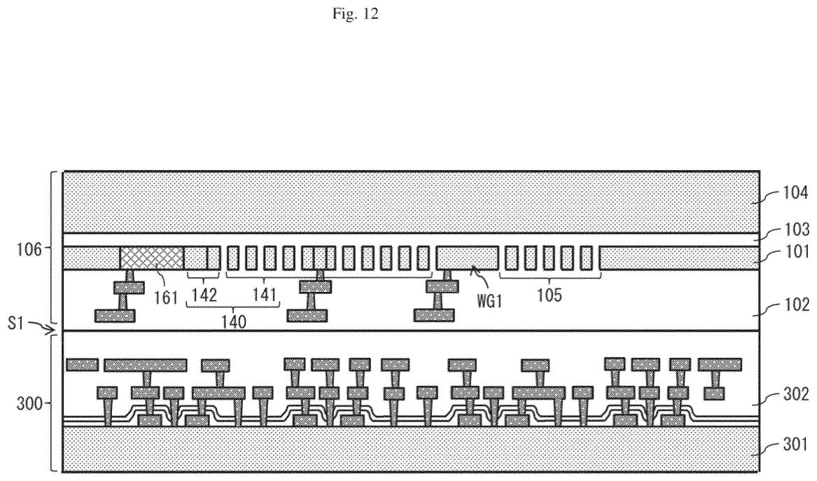

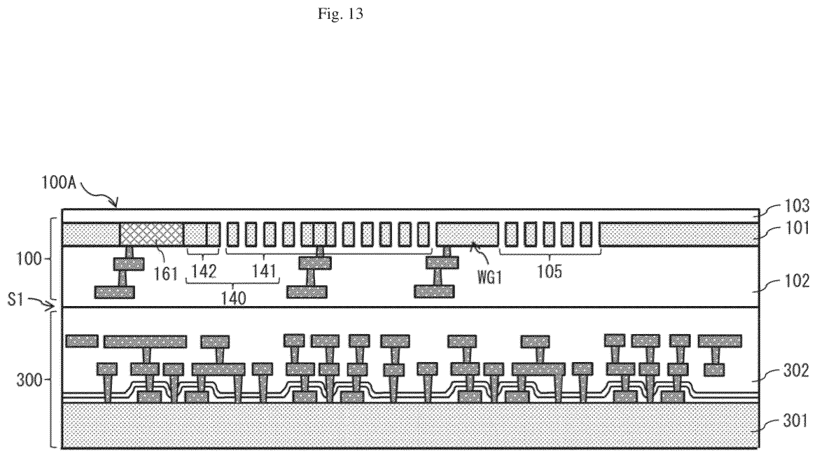

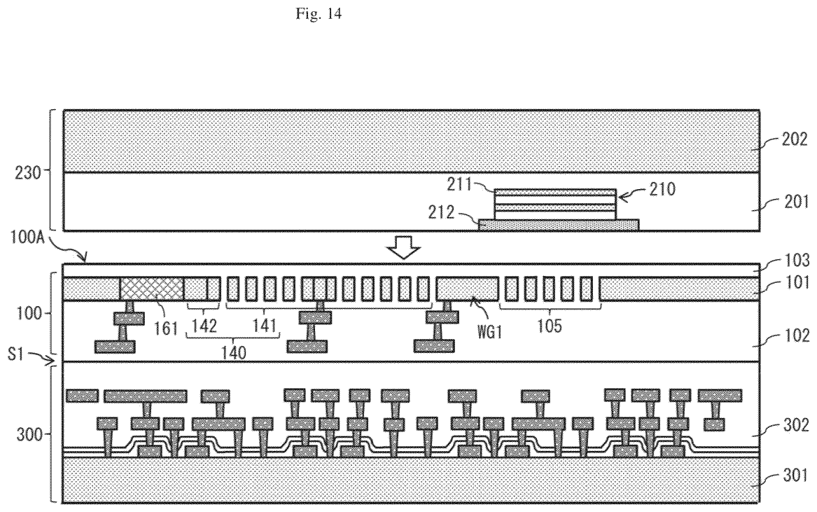

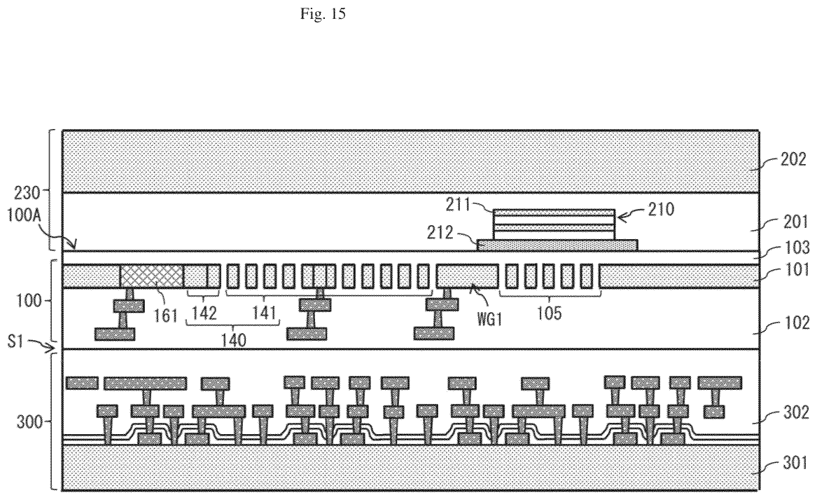

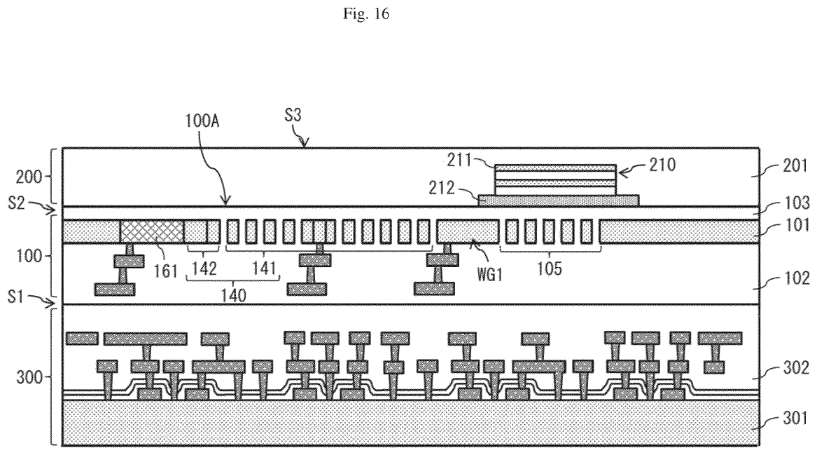

Next, the SOI substrate 106 and the third die 300 are bonded together with a front surface of the interlayer insulating film 102 and a front surface of the interlayer insulating film 302 opposed to each other (FIGS. 11 and 12). Next, the Si substrate 104 in the SOI substrate 106 is removed (FIG. 13). Thus, the PIC substrate 100A is formed on the third die 300. Subsequently, the PIC substrate 100A and a laser substrate 230 are bonded together with a front surface of the BOX layer 103 and the front surface of the semiconductor substrate 201 opposed to each other (FIGS. 14 and 15). Next, a Si substrate 202 in laser substrate 230 is removed (FIG. 16). Thus, the second die 200 is formed on the first die 100.

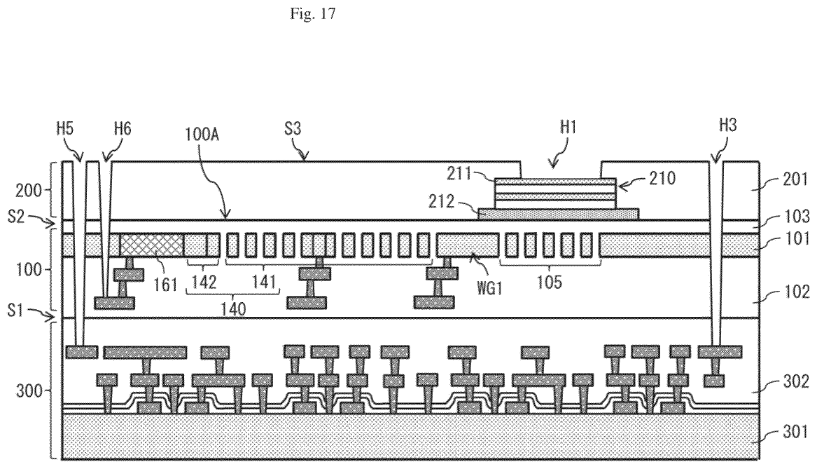

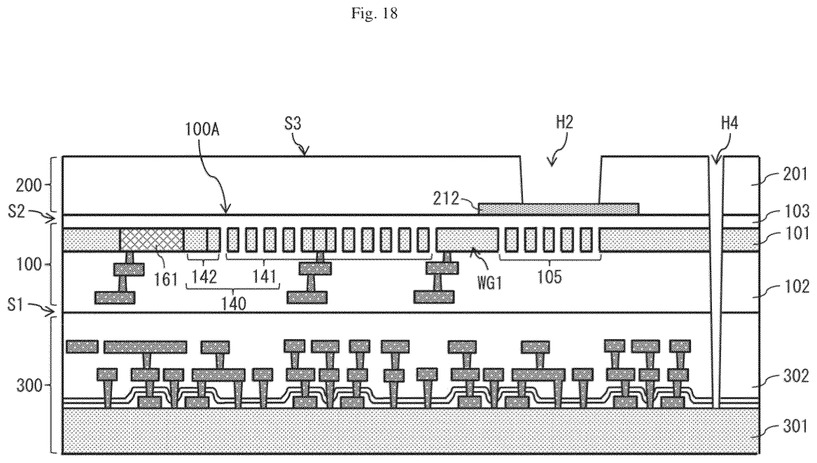

Next, via holes H1 to H6 are formed in the semiconductor substrate 201 (FIGS. 17 and 18). Thus, the contact layer 211 is exposed on a bottom surface of the via hole H1, the contact layer 212 is exposed on a bottom surface of the via hole H2, a wiring layer in the interlayer insulating film 302 is exposed on a bottom surface of the via hole H3, and the Si substrate 301 is exposed on a bottom surface of the via hole H4. Furthermore, a wiring layer in the interlayer insulating film 302 is exposed on a bottom surface of the via hole H5, and a wiring layer electrically coupled to the Ge-PD 161 is exposed on a bottom surface of the via hole H6.

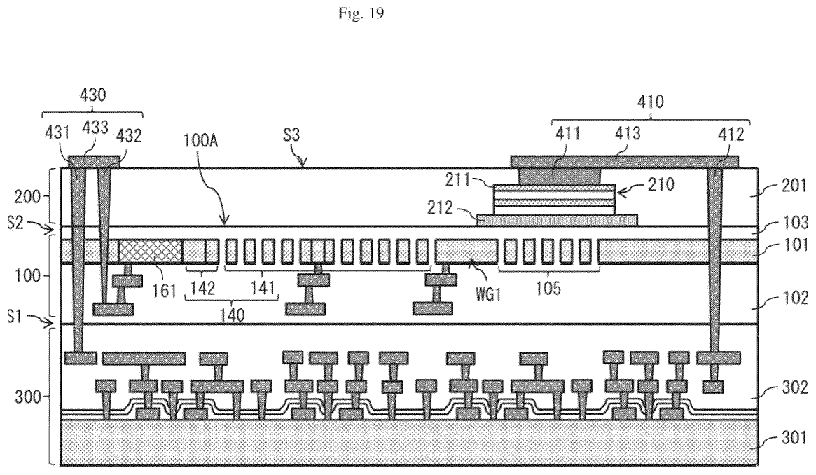

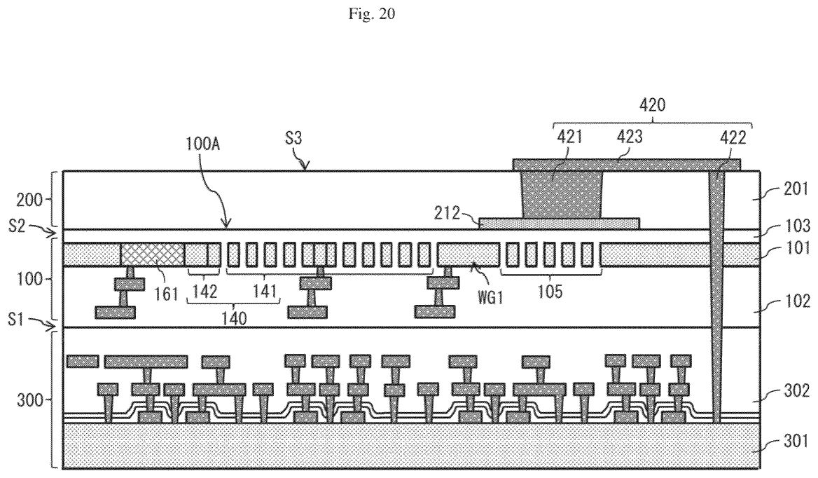

Next, a metal is embedded in the via holes H1 to H6 (FIGS. 19 and 20). Thus, the vias 411, 412, 421, 422, 431, and 432 are formed. Subsequently, a metal that couples the via 411 and the via 412 to each other, a metal that couples the via 421 and the via 422 to each other, and a metal that couples the via 431 and the via 432 to each other are formed (FIGS. 19 and 20). Thus, the wiring layers 413, 423, and 433 are formed. Finally, the lens 220 is disposed. Thus, the distance measuring device 1000 is manu-factured.

### Effects

Next, description is given of effects of the distance measuring device 1000.

In the present embodiment, the second die 200 (laser 210) is electrically coupled to the third die 300 (signal processing circuit) through the wiring lines 410 and 420. Furthermore, the first die 100 (detector 160) is electrically coupled to the third die 300 (signal processing circuit) through the wiring line 430. This makes it possible to discharge heat generated in the laser 210 and heat generated in the detector 160 to the Si substrate 301 through the wiring lines 410, 420, and 430. As a result, it is possible to suppress instability of operation caused by heat generation in the laser 210 and the detector 160.

In the present embodiment, portions of the wiring lines 410, 420, and 430 include the vias 411, 412, 421, 422, 431, and 432. This makes it possible to increase cross-sectional areas of the wiring lines 410, 420, and 430, as compared with a wiring layer formed by patterning, which makes it possible to efficiently discharge heat generated in the laser 210 and heat generated in the detector 160 to the Si substrate 301. As a result, it is possible to suppress instability of operation caused by heat generation in the laser 210 and the detector 160.

In the present embodiment, in the PIC substrate 100A, the optical waveguide WG1, the splitter 120, the optical waveguides WG2 and WG3, the coupler 150, and the Ge-PDs 161 and 162 are provided in the common Si layer 101. In addition, the controller 310, the DAC 320, the ADC 330, and the FFT 340 are provided in the third die 300 (signal processing substrate). Furthermore, the PIC substrate 100A and the second die 200 are stacked on the third die 300, and are electrically coupled to the third die 300 through the wiring lines 410, 420, and 430. This allows for downsizing, as compared with a module in which a plurality of RF components is coupled through an optical fiber. An electrical signal path subsequent to the Ge-PDs 161 and 162 is shortened by the downsizing, which makes it possible to reduce mixing of external noise into an electrical signal.

In the present embodiment, the modulator 110 and the Si antenna 141 are provided in the Si layer 101. The modulator 110 generates the transmission signal Stx (chirp signal). The Si antenna 141 outputs the transmission signal Stx1 divided from the transmission signal Stx to outside, and receives the return signal Srx from the outside. This allows for downsizing, as compared with a module in which a plurality of RF components is coupled through an optical fiber.

In the present embodiment, the diffraction grating 105 is provided at a location opposed to the laser 210 (directly below the laser 210). The diffraction grating 105 guides the laser light L emitted from the laser 210 into the optical waveguide WG1. This allows for downsizing, as compared with a module in which a plurality of RF components is coupled through an optical fiber. A propagation path of the laser light L is shortened by the downsizing, which makes it possible to reduce loss of the laser light L.

### 2. Modification Examples of First Embodiment

Next, description is given of modification examples of the distance measuring device 1000 according to the embodiment described above.

### Modification Example 2-1

FIG. 21 illustrates an exemplary cross-sectional configuration of the distance measuring device 1000 according a modification example. FIG. 21 illustrates a modification example of the cross-sectional configuration in FIG. 5. In the embodiment described above, for example, the via 422 may be in contact with the wiring layer 423 and a wiring layer in the interlayer insulating film 302, as illustrated in FIG. 21. Even in such a case, it is possible to discharge heat generated in the laser 210 to the Si substrate 301 through the wiring line 420 including the via 422. As a result, it is possible to suppress instability of operation caused by heat generation in the laser 210.

### Modification Example 2-2

FIG. 22 illustrates an exemplary cross-sectional configuration of the distance measuring device 1000 according to a modification example. FIG. 22 illustrates a modification example of the cross-sectional configuration illustrated in FIG. 5. In the embodiment described above and the modification example thereof, in the interlayer insulating film 102 of the PIC substrate 100A, for example, a heat dissipation member 107 may be provided at a location opposed to the laser 210 (directly below the laser 210), as illustrated in FIG. 22. The heat dissipation member 107 may include a metal (e.g., Cu). The heat dissipation member 107 may be provided, for example, in the same layer as another circuit wiring line in the interlayer insulating film 102, and may include the same material as the other wiring line in the interlayer insulating film 102. The heat dissipation member 107 may serve as a portion of a circuit wiring line in the distance measuring device 1000, or may not function as a circuit wiring line in the distance measuring device 1000. To stabilize a potential of the heat dissipation member 107, a wiring line that couples the heat dissipation member 107 and a constant potential wiring line to each other may be provided in the interlayer insulating film 102.

In the present modification example, in the interlayer insulating film 102 of the PIC substrate 100A, the heat dissipation member 107 is provided at a location opposed to the laser 210 (directly below the laser 210). This makes it possible to efficiently discharge heat generated in the laser 210 to the Si substrate 301 through the heat dissipation member 107. As a result, it is possible to suppress instability of operation caused by heat generation in the laser 210.

### Modification Example 2-3

FIG. 23 illustrates an exemplary planar configuration of the distance measuring device 1000 according to a modification example. FIG. 24 illustrates an example of a cross-sectional configuration taken along a line A-A in FIG. 23. In the embodiment described above and the modification examples thereof, the second die 200 may include, for example, a heat dissipation member 440 on the front surface of the semiconductor substrate 201, as illustrated in FIGS. 23 and 24. The heat dissipation member 440 may be provided separately from the wiring lines 410 and 420, and may include, for example, a metal (e.g., Cu). The heat dissipation member 440 may serve as a portion of a circuit wiring line in the distance measuring device 1000, or may not function as a circuit wiring line in the distance measuring device 1000. FIG. 24 ex-emplifies a case where the heat dissipation member 440 does not function as a portion of the circuit wiring line in the distance measuring device 1000.

The heat dissipation member 440 includes, for example, a via 441 and a wiring layer 442. The via 441 is in contact with the contact layer 211 and the wiring layer 442. The via 441 is provided in the semiconductor substrate 201, and extends in the stacking direction of the semiconductor substrate 201. The via 441 includes, for example, a metal (e.g., Cu) embedded in a via hole provided in the semiconductor substrate 201. The wiring layer 442 includes a metal (e.g., Cu). The wiring layer 442 is disposed on the front surface of the semiconductor substrate 201, and is in contact with the via 441. In such a case, it is possible to efficiently discharge heat generated in the laser 210 to outside through the heat dissipation member 440. As a result, it is possible to suppress instability of operation caused by heat generation in the laser 210.

### 3. Second Embodiment

Next, description is given of a distance measuring device 2000 according to a second embodiment of the present disclosure. In the following, common components to those in the embodiment described above are denoted by same reference signs, and description thereof is omitted as appropriate.

### Configuration

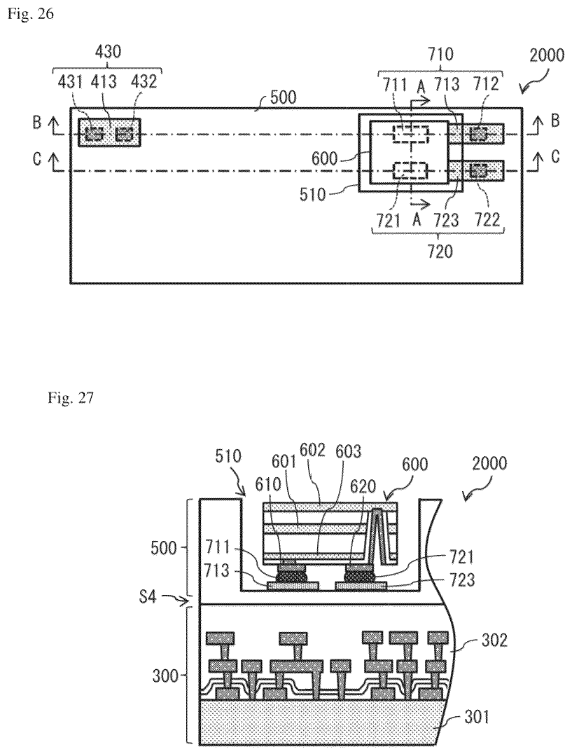

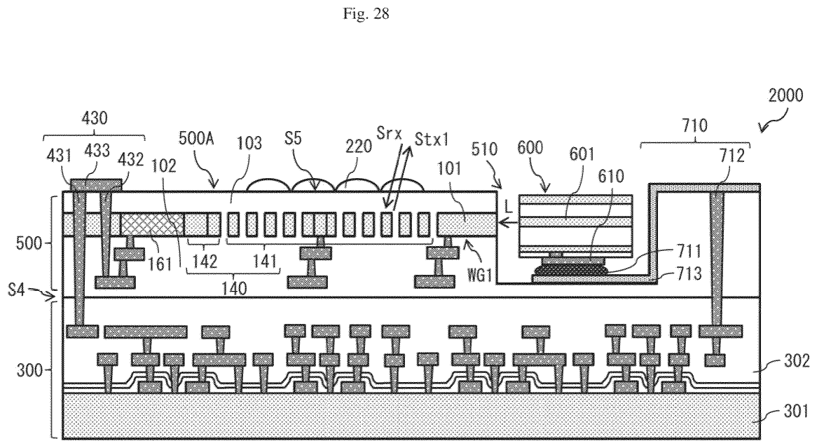

FIG. 25 illustrates an exemplary schematic configuration of the distance measuring device 2000 according to a second embodiment of the present disclosure. FIG. 26 illustrates an exemplary planar configuration of the distance measuring device 2000. FIG. 27 illustrates an exemplary cross-sectional configuration taken along a line A-A in FIG. 26. FIG. 28 illustrates an exemplary cross-sectional configuration taken along a line B-B in FIG. 26. FIG. 29 illustrates an exemplary cross-sectional configuration taken along a line C-C in FIG. 26.

The distance measuring device 2000 includes an FMCW LiDAR. The distance measuring device 2000 includes, for example, a first die 500, a laser chip 600, and the third die 300, as illustrated in FIG. 25. The first die 500 is stacked on the third die 300, and is coupled to the third die 300 through a joining surface S4 between the first die 500 and the third die 300. A top surface of the first die 500 serves as the entrance/exit surface S3.

### (Laser Chip 600)

The laser chip 600 is a light source chip that outputs a light signal. The laser chip 600 is a chip-shaped edge emitting semiconductor laser, and emits the laser light L having a predetermined fixed wavelength (e.g., 1550 nm) from an end surface of an active layer 601 in accordance with control by the controller 310. The laser chip 600 is mounted in a recessed section 510 to cause the laser light L to enter an inner surface (optical waveguide WG1) of the recessed section 510 of a PIC substrate 500A to be described later. The laser chip 600 is mounted in the recessed section 510 to set a light spot (light spot generated on the end surface of the active layer 601) of the laser chip 600 at the same height as the Si layer 101 (optical waveguide WG1).

The laser chip 600 includes, for example, the active layer 601, a pair of cladding layers, a contact layer (first contact layer), and a contact layer (second contact layer). The active layer 601 is sandwiched between the pair of cladding layers in the thickness direction. The contact layer (first contact layer) is ohmically coupled to one of the cladding layers, and the contact layer (second contact layer) is ohmically coupled to the other cladding layer. The laser chip 600 further includes, for example, an electrode 610 and an electrode 620. The electrode 610 is in contact with the first contact layer, and the electrode 620 is electrically coupled to the second contact layer through a via. The electrodes 610 and 620 are disposed, for example, on a common surface of the laser chip 600 (e.g., a bottom surface of the laser chip 600). The electrodes 610 and 620 include, for example, copper (Cu). The laser chip 600 is electrically coupled to the third die 300 (signal processing circuit) through the electrodes 610 and 620 and wiring lines 710 and 720 to be described later.

### (First Die 500)

The first die 500 includes, for example, the modulator 110, the splitter 120, the circulator 130, the antenna 140, the coupler 150, and the detector 160, as illustrated in FIG. 25. In the first die 500, the modulator 110, the splitter 120, the circulator 130, the antenna 140, the coupler 150, and the detector 160 are provided in the PIC substrate 500A.

The PIC substrate 500A includes, for example, the Si layer 101, the interlayer insulating film 102, and the BOX layer 103, as illustrated in FIGS. 27 to 29. The Si layer 101 is sandwiched between the interlayer insulating film 102 and the BOX layer 103. The PIC substrate 500A is obtained by removing the Si substrate 104 from the SOI substrate 106. The BOX layer 103 includes a SiO₂ layer. The interlayer insulating film 102 is a layer provided on the SOI substrate 106, and has a configuration in which a plurality of patterned wiring layers and a via that couples the wiring layers to each other are provided in a plurality of SiO₂ layers stacked. The front surface of the interlayer insulating film 102 serves as a bottom surface of the first die 500. The front surface of the interlayer insulating film 102 serves as a top surface of the first die 500, and serves as an entrance/exit surface S5.

The optical waveguides WG1, WG2, and WG3 are provided in the Si layer 101. The optical waveguide WG1 extends, for example, from the inner surface (side surface) of the recessed section 510 to be described later to the antenna 140 through the modulator 110, the splitter 120, and the circulator 130. The optical waveguide WG2 is an optical wavelength branching from the optical waveguide WG1 in the splitter 120, and is coupled to one input end (optical waveguide 151) of the coupler 150. The optical waveguide WG3 is an optical waveguide branching from the optical waveguide WG1 in the circulator 130, and is coupled to another input end (optical waveguide 152) of the coupler 150.

The lens 220 is bonded to a region (entrance/exit surface S5) opposed to the Si antenna 141 of a front surface of the first die 500. The transmission signal Stx1 is outputted from the entrance/exit surface S5, and the return signal Srx enters the entrance/exit surface S5. The lens 220 is bonded to the entrance/exit surface S5, and the transmission signal Stx is outputted from the antenna 140 to outside through the lens 220 and the entrance/exit surface S5, and the return signal Srx enters the antenna 140 from the outside through the lens 220 and the entrance/exit surface S5.

The PIC substrate 500A has the recessed section 510 that accommodates the laser chip 600. The optical waveguide WG1 (Si layer 101) is exposed on the inner surface (side surface) of the recessed section 510. An insulating film such as an antireflection film may be provided on the inner surface (side surface) of the recessed section 510. The antireflection film prevents (or reduces) reflection of light from the laser chip 600.

The first die 500 includes a wiring line that electrically couples the laser chip 600 and the third die 300 (signal processing circuit) to each other. The first die 500 includes, as the wiring line described above, for example, the wiring line 710 in contact with the electrode 610 of the laser chip 600, and the wiring line 720 in contact with the electrode 620 of the laser chip 600, as illustrated in FIGS. 26 to 29. The wiring lines 710 and 720 correspond to specific examples of a “first wiring line” according to an embodiment of the present disclosure. Of the wiring lines 710 and 720, one wiring line serves as a wiring line of a cathode of the laser chip 600, and the other wiring line serves as a wiring line of an anode of the laser chip 600. Hereinafter, the wiring line 710 serves as the wiring line of the cathode of the laser chip 600, and the wiring line 720 serves as the wiring line of the anode of the laser chip 600. It is to be noted that, depending on the structure of the laser chip 600, the wiring line 710 may serve as the wiring line of the anode of the laser chip 600, and the wiring line 720 may serve as the wiring line of the cathode of the laser chip 600.

The wiring line 710 includes, for example, a solder 711, a via 712, and a wiring layer 713, as illustrated in FIGS. 26 to 28. The wiring line 720 includes, for example, a solder 721, a via 722, and a wiring layer 723, as illustrated in FIGS. 26, 27, and 29. The wiring line 710 and the wiring line 720 include, for example, Cu. The laser chip 600 is electrically coupled to the third die 300 (signal processing circuit) through the wiring lines 710 and 720.

The solder 711 is in contact with the electrode 610 and the wiring layer 713. The solder 711 is provided on a front surface, at a location opposed to the bottom surface of the recessed section 510, of the wiring layer 713. The via 712 is in contact with the wiring layer 713 and a wiring layer in the interlayer insulating film 302. The via 712 is provided in the first die 500 and the third die 300, and extends from the BOX layer 103 to the interlayer insulating film 302. The via 712 includes, for example, a metal (e.g., Cu) embedded in a via hole provided from the BOX layer 103 to the interlayer insulating film 302. The wiring layer 713 is in contact with the solder 711 and the via 712. The wiring layer 713 includes a metal (e.g., Cu), and is disposed on the bottom surface and the side surface of the recessed section 510 and the front surface of the first die 500.

The solder 721 is in contact with the electrode 620 and the wiring layer 723. The solder 721 is provided on a front surface, at a location opposed to the bottom surface of the recessed section 510, of the wiring layer 723. The via 722 is in contact with the wiring layer 723 and the Si substrate 301. The via 722 is provided in the first die 500 and the third die 300, and extends from the BOX layer 103 to the interlayer insulating film 302. The via 722 includes, for example, a metal (e.g., Cu) embedded in a via hole provided from the BOX layer 103 to the interlayer insulating film 302. The wiring layer 723 is in contact with the solder 711 and the via 712. The wiring layer 723 includes a metal (e.g., Cu), and is disposed on the bottom surface and the side surface of the recessed section 510 and the front surface of the first die 500.

A metal bump may be used in place of the solder 711. In addition, a metal bump may be used in place of the solder 721.

The first die 500 further includes, for example, the wiring line 430 that electrically couples the detector 160 and the third die 300 (signal processing circuit) to each other. The wiring line 430 includes, for example, the via 431, the via 432, and the wiring layer 433, as illustrated in FIGS. 26 and 28. The wiring line 430 includes, for example, copper (Cu). The first die 100 (detector 160) is electrically coupled to the third die 300 (signal processing circuit) through the wiring line 430.

The via 431 is in contact with a wiring layer (e.g., Cu) in the interlayer insulating film 302 and the wiring layer 433. The via 431 extends from the BOX layer 103 to the interlayer insulating film 302. The via 431 includes, for example, a metal (e.g., Cu) embedded in a via hole provided from the BOX layer 103 to the interlayer insulating film 302. The via 432 is in contact with a wiring layer (e.g., Cu) in the interlayer insulating film 102 and the wiring layer 433 that are electrically coupled to the detector 160. The via 432 extends from the BOX layer 103 to the interlayer insulating film 102. The via 432 includes, for example, a metal (e.g., Cu) embedded in a via hole provided from the BOX layer 103 to the interlayer insulating film 102. The wiring layer 433 is disposed on the front surface of the BOX layer 103, and is in contact with the via 431 and the via 432. The wiring layer 433 includes a metal (e.g., Cu).

### Effects

Next, description is given of effects of the distance measuring device 2000.

In the present embodiment, the laser chip 600 is electrically coupled to the third die 300 (signal processing circuit) through the wiring lines 710 and 720. Furthermore, the first die 500 (detector 160) is electrically coupled to the third die 300 (signal processing circuit) through the wiring line 430. This makes it possible to discharge heat generated in the laser chip 600 and heat generated in the detector 160 to the Si substrate 301 through the wiring lines 710, 720, and 430. As a result, it is possible to suppress instability of operation caused by heat generation in the laser chip 600 and the detector 160.

In the present embodiment, portions of the wiring lines 710, 720, and 430 include the vias 712, 722, 431, and 432. This makes it possible to increase cross-sectional areas of the wiring lines 710, 720, and 430, as compared with a wiring layer formed by patterning, which makes it possible to efficiently discharge heat generated in the laser chip 600 and heat generated in the detector 160 to the Si substrate 301. As a result, it is possible to suppress instability of operation caused by heat generation in the laser chip 600 and the detector 160.

In the present embodiment, in the PIC substrate 500A, the optical waveguide WG1, the splitter 120, the optical waveguides WG2 and WG3, the coupler 150, and the Ge-PDs 161 and 162 are provided in the common Si layer 101. In addition, the controller 310, the DAC 320, the ADC 330, and the FFT 340 are provided in the third die 300 (signal processing substrate). Furthermore, the PIC substrate 500A is stacked on the third die 300, and is electrically coupled to the third die 300 through the wiring lines 710, 720, and 430. This allows for downsizing, as compared with a module in which a plurality of RF components is coupled through an optical fiber. An electrical signal path subsequent to the Ge-PDs 161 and 162 is shortened by the downsizing, which makes it possible to reduce mixing of external noise into an electrical signal.

In the present embodiment, the recessed section 510 that accommodates the laser chip 600 is provided in the PIC substrate 500A, and the laser light L emitted from the laser chip 600 is introduced from an end section of the optical waveguide WG1 (Si layer 101) exposed on the inner surface (side surface) of the recessed section 510. This allows for downsizing, as compared with a module in which a plurality of RF components is coupled through an optical fiber. A propagation path of the laser light L is shortened by the downsizing, which makes it possible to reduce loss of the laser light L.

### 4. Modification Examples of Second Embodiment

Next, description is given of modification examples of the distance measuring device 2000 according to the second embodiment described above.

### Modification Example 4-1

FIG. 30 illustrates an exemplary cross-sectional configuration of the distance measuring device 2000 according a modification example. FIG. 30 illustrates a modification example of the cross-sectional configuration in FIG. 29. In the second embodiment described above, the via 722 may be in contact with the wiring layer 723 and a wiring layer in the interlayer insulating film 302, as illustrated in FIG. 30. Even in such a case, it is possible to discharge heat generated in the laser chip 600 to the Si substrate 301 through the wiring line 720 including the via 722. As a result, it is possible to suppress instability of operation caused by heat generation in the laser chip 600.

### Modification Example 4-2

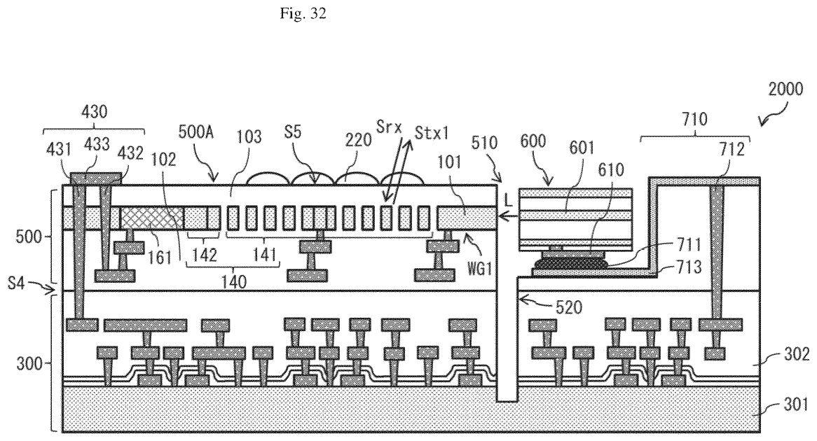

FIGS. 31 and 32 each illustrate an exemplary cross-sectional configuration of the distance measuring device 2000 according to a modification example. FIGS. 31 and 32 each illustrate a modification example of the cross-sectional configuration illustrated in FIG. 28. In the second embodiment described above and the modification example thereof, for example, a groove section 520 may be provided on the bottom surface of the recessed section 510, as illustrated in FIGS. 31 and 32. The groove section 520 may have a depth that penetrates through the PIC substrate 500A, as illustrated in FIG. 31. The groove section 520 may have, for example, a depth that penetrates not only through the PIC substrate 500A but also through the interlayer insulating film 302, as illustrated in FIG. 32.

The groove section 520 is provided at least in a region between the optical waveguide WG1 and the laser chip 600 of the bottom surface of the recessed section 510 in a plan view. The groove section 520 may have, for example, a length that crosses the region between the optical waveguide WG1 and the laser chip 600 of the bottom surface of the recessed section 510 in a plan view, as illustrated in FIG. 33. In addition, for example, the groove section 520 may be provided to surround three side surfaces including a light-emitting surface of the laser chip 600 in a plan view, as illustrated in FIGS. 34 and 35. On this occasion, for example, a plurality of groove sections 520 may be provided one for each of the three side surfaces of the laser chip 600, as illustrated in FIG. 34. Alternatively, for example, one groove section 520 may have a U-shape that surrounds the three side surfaces including the light-emitting surface of the laser chip 600, as illustrated in FIG. 35.

Thus, in the present modification example, the groove section 520 is provided at least in the region between the optical waveguide WG1 and the laser chip 600 of the bottom surface of the recessed section 510 in a plan view. Accordingly, the groove section 520 makes it difficult to propagate heat generated in the laser chip 600 to the optical waveguide WG1. As a result, it is possible to suppress instability of operation caused by heat generation in the laser chip 600. In other words, in the present modification example, the groove section 520 serves to hinder heat generated in the laser chip 600 from propagating to the waveguide WG1.

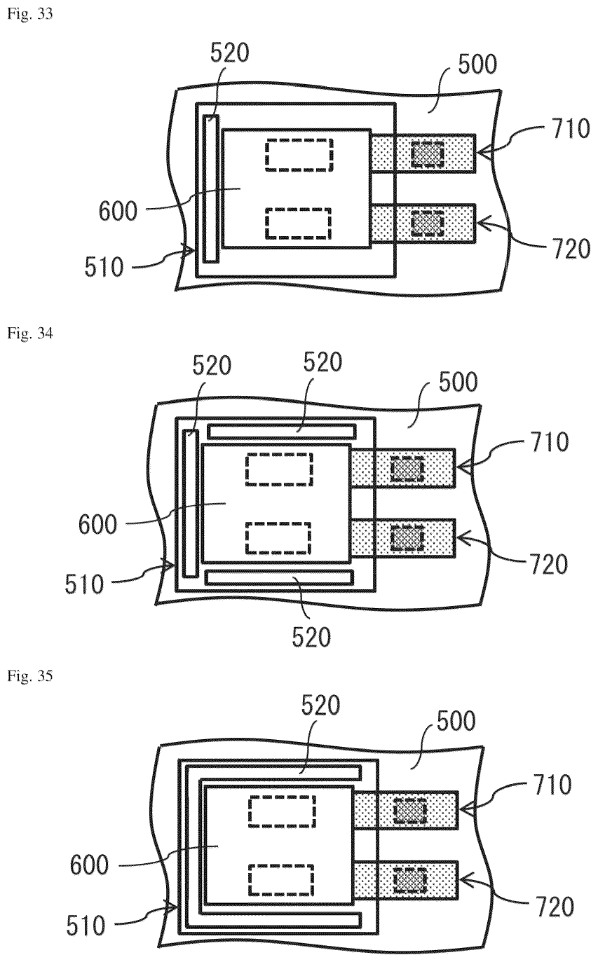

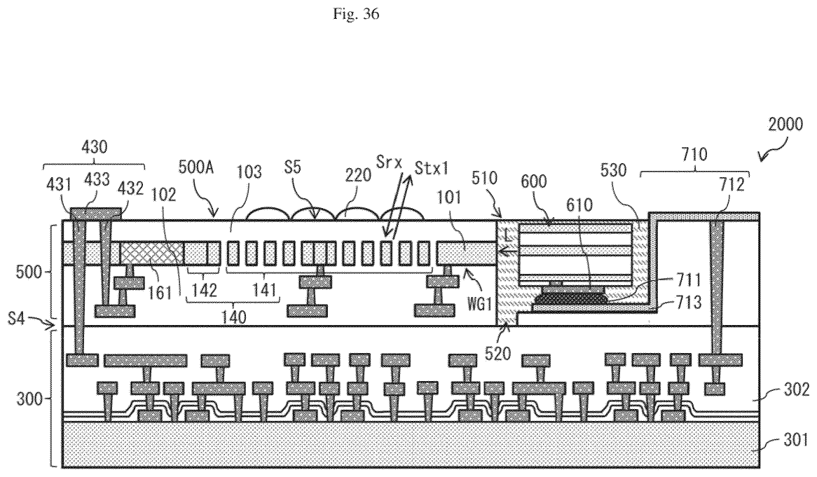

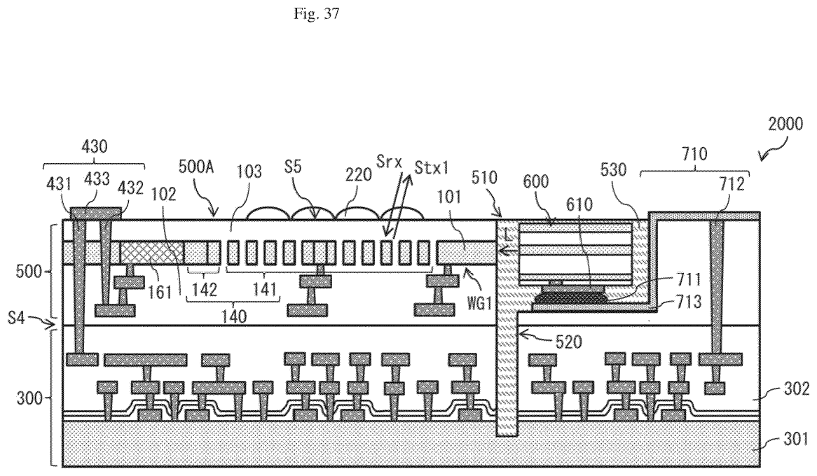

In the present modification example, for example, a resin member 530 may be embedded in the recessed section 510 and the groove section 520, as illustrated in FIGS. 36 and 37. The resin member 530 includes a resin material (transparent resin material) that allows laser light to pass therethrough, and includes, for example, epoxy, acrylic, acrylate, or the like. Embedding the resin member 530 in the recessed section 510 and the groove section 520 in such a manner makes it possible to suppress falling out of the laser chip 600 or occurrence of displacement of the laser chip 600. As a result, it is possible to suppress instability of operation caused by a decrease in an optical coupling property between the laser chip 600 and the optical waveguide WG1.

### Modification Example 4-3

FIGS. 38 and 39 each illustrate an exemplary cross-sectional configuration of the distance measuring device 2000 according to a modification example. FIG. 38 illustrates a modification example of the cross-sectional configuration illustrated in FIG. 28. FIG. 39 illustrates a modification example of the cross-sectional configuration illustrated in FIG. 29. In the second embodiment described above and the modification examples thereof, for example, a via hole 540 may be provided on the bottom surface of the recessed section 510, as illustrated in FIG. 38. For example, the via hole 540 may have a depth that penetrates through the PIC substrate 500A and reaches a wiring layer in the interlayer insulating film 302, as illustrated in FIG. 38. On this occasion, the wiring layer in the interlayer insulating film 302 is exposed on a bottom surface of the via hole 540. Furthermore, in the second embodiment described above and the modification examples thereof, for example, a via hole 550 may be provided on the bottom surface of the recessed section 510, as illustrated in FIG. 39. For example, the via hole 550 may have a depth that penetrates through the PIC substrate 500A and the interlayer insulating film 302 and reaches the Si substrate 301, as illustrated in FIG. 39. On this occasion, the Si substrate 301 is exposed on the bottom surface of the via hole 550.

In the present modification example, the wiring line 710 in contact with the electrode 610 of the laser chip 600 extends from the bottom surface of the recessed section 510 along a side surface and the bottom surface of the via hole 540. The wiring line 710 is in contact with the wiring layer in the interlayer insulating film 302 through the via hole 540. It is to be noted that a portion extending along the side surface and the bottom surface of the via hole 540 of the wiring line 710 corresponds to a via.

In the present modification example, the wiring line 720 in contact with the electrode 620 of the laser chip 600 extends from the bottom surface of the recessed section 510 to a side surface and the bottom surface of the via hole 550. The wiring line 720 is in contact with the Si substrate 301 through the via hole 550. It is to be noted that a portion extending along the side surface and the bottom surface of the via hole 550 of the wiring line 720 corresponds to a via.

Thus, in the present modification example, the wiring line 710 is in contact with the wiring layer in the interlayer insulating film 302 through the via hole 540, and the wiring line 720 is in contact with the Si substrate 301 through the via hole 550. This makes it possible for the wiring lines 710 and 720 not only to electrically couple the laser chip 600 and the controller 310 to each other, but also to discharge heat generated in the laser chip 600 to the Si substrate 301 through the wiring lines 710 and 720. As a result, it is possible to suppress instability of operation caused by heat generation in the laser chip 600.

### Modification Example 4-4

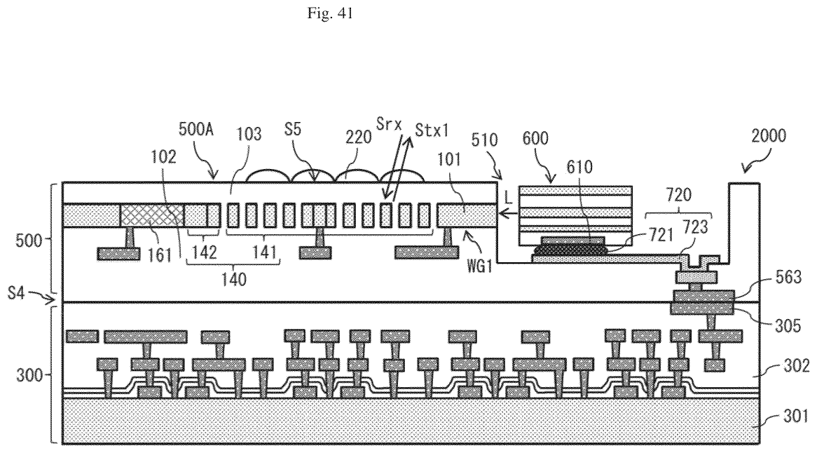

FIGS. 40 and 41 each illustrate an exemplary cross-sectional configuration of the distance measuring device 2000 according to a modification example. FIG. 40 illustrates a modification example of the cross-sectional configuration illustrated in FIG. 28. FIG. 41 illustrates a modification example of the cross-sectional configuration illustrated in FIG. 29. In the second embodiment described above and the modification examples thereof, for example, the first die 500 and the third die 300 are bonded together to join pad electrodes 561, 562, and 563 provided on the first die 500 (PIC substrate 500A) and pad electrodes 303, 304, and 305 on the third die 300 (interlayer insulating film 302) to each other, as illustrated in FIGS. 40 and 41.

The pad electrode 561 configures a portion of the wiring line 710, and is electrically coupled to the wiring layer 713. The wiring layer 713 electrically couples the laser chip 600 and the pad electrode 561 to each other. The pad electrode 562 is electrically coupled to, for example, the Ge-PD 161. The pad electrode 563 configures a portion of the wiring line 720, and is electrically coupled to the wiring line 723. The wiring layer 723 electrically couples the laser chip 600 and the pad electrode 563 to each other. The pad electrodes 303, 304, 305, 561, 562, and 563 each include a metal (e.g., a cupper pad). The wiring lines 710 and 720 each electrically couple the laser chip 600 and the third die 300 (interlayer insulating film 302) to each other. The wiring lines 710 and 720 correspond to specific examples of a “second wiring line” according to the first embodiment of the present disclosure.

For example, the wiring layers 713 and 723 may be electrically coupled to the pad electrodes 561 and 563 through openings provided on the bottom surface of the recessed section 510, as illustrated in FIGS. 40 and 41. Portions of the wiring layers 713 and 723 may include a metal material different from those of the pad electrodes 303, 304, 305, 561, 562, and 563. The portions of the wiring layers 713 and 723 may include a material (e.g., aluminum (Al)) having high heat dissipation, as compared with those of the pad electrodes 303, 304, 305, 561, 562, and 563.

Thus, in the present modification example, the first die 500 and the third die 300 are bonded together to cause the pad electrodes 561, 562, and 563 and the pad electrodes 303, 304, and 305 to be in contact with each other. Even in such a case, it is possible to discharge heat generated in the laser chip 600 and heat generated in the detector 160 to the Si substrate 301 through the wiring lines 710 and 720 and the pad electrodes 562 and 304. As a result, it is possible to suppress instability of operation caused by heat generation in the laser 210 and the detector 160.

In the present modification example, for example, the groove section 520 may be provided on the bottom surface of the recessed section 510, as illustrated in FIGS. 42, 43, and 44, The groove section 520 may have, for example, a depth that penetrates through the PIC substrate 500A, or may have a depth that penetrates through not only the PIC substrate 500A but also the interlayer insulating film 302.

The groove section 520 is provided at least in a region between the optical waveguide WG1 and the laser chip 600 of the bottom surface of the recessed section 510 in a plan view. The groove section 520 may have, for example, a length that crosses the region between the optical waveguide WG1 and the laser chip 600 of the bottom surface of the recessed section 510 in a plan view, as illustrated in FIG. 42. In addition, for example, the groove section 520 may be provided to surround four side surfaces including the light-emitting surface of the laser chip 600 in a plan view, as illustrated in FIGS. 43 and 44. On this occasion, for example, a plurality of groove sections 520 may be provided one for each of the four side surfaces of the laser chip 600, as illustrated in FIG. 43. Alternatively, for example, one groove section 520 may have a ring shape that surrounds the laser chip 600, as illustrated in FIG. 44.

Thus, in the present modification example, in a case where the groove section 520 is provided at least in the region between the optical waveguide WG1 and the laser chip 600 of the bottom surface of the recessed section 510 in a plan view, the groove section 520 makes it difficult to propagate heat generated in the laser chip 600 to the optical waveguide WG1. As a result, it is possible to suppress instability of operation caused by heat generation in the laser chip 600.

In the present modification example, the resin member 530 may be embedded in the recessed section 510 and the groove section 520. Embedding the resin member 530 in the recessed section 510 and the groove section 520 in such a manner makes it possible to prevent (or reduce) falling out of the laser chip 600 or occurrence of displacement of the laser chip 600. As a result, it is possible to suppress instability of operation caused by a decrease in the optical coupling property between the laser chip 600 and the optical waveguide WG1.

### Modification Example 4-5

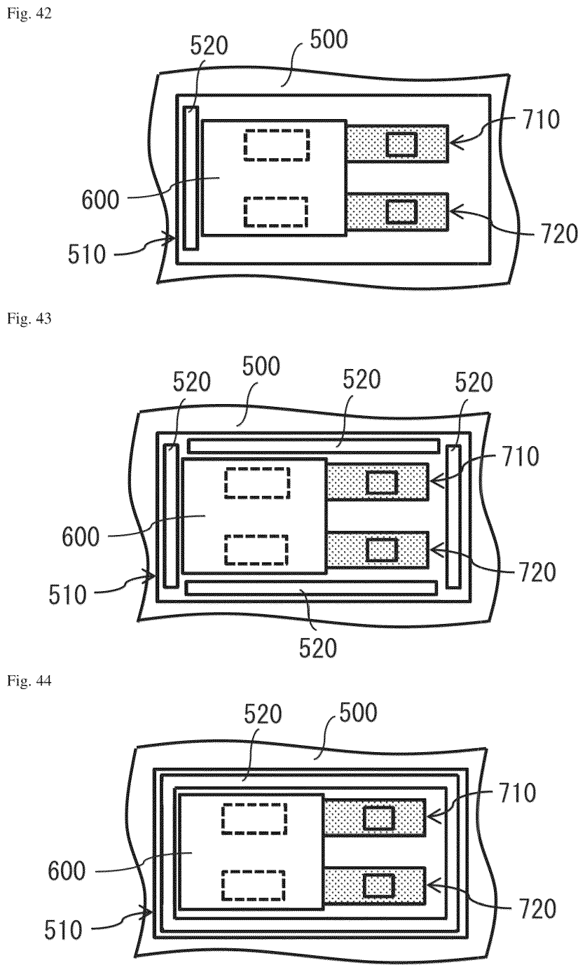

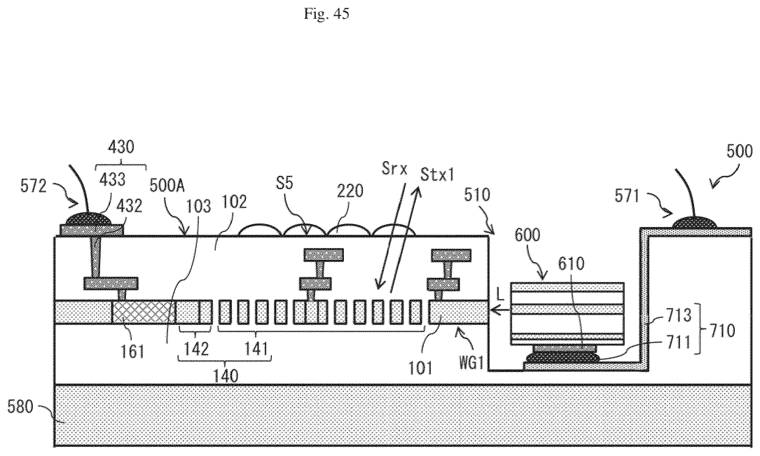

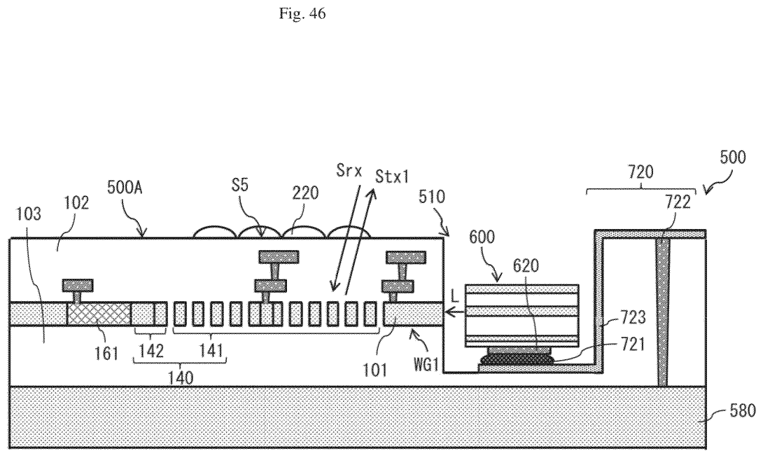

FIGS. 45 and 46 each illustrate an exemplary cross-sectional configuration of the distance measuring device 2000 according to a modification example. FIG. 45 illustrates a modification example of the cross-sectional configuration illustrated in FIG. 28. FIG. 46 illustrates a modification example of the cross-sectional configuration illustrated in FIG. 29. In the second embodiment described above and the modification examples thereof, the first die 500 may not be stacked on the third die 300, and the first die 500 and the third die 300 may be separately disposed. On this occasion, for example, the wiring line 710 may be electrically coupled to the third die 300 (signal processing circuit) through a bonding wire 571, as illustrated in FIG. 45. The bonding wire 571 is in contact with, for example, the wiring layer 713. For example, the wiring line 430 may be electrically coupled to the third die 300 (signal processing circuit) through a bonding wire 572, as illustrated in FIG. 45. The bonding wire 572 is in contact with, for example, a front surface of the wiring layer 433. The bonding wires 571 and 572 include, for example, gold (Au).

In the present modification example, for example, the PIC substrate 500A is stacked on a support substrate 580, as illustrated in FIGS. 45 and 46. On this occasion, a front surface, on side of the interlayer insulating film 102, of the PIC substrate 500A serves as the entrance/exit surface S5. In addition, in the wiring line 720, the via 722 is in contact with the support substrate 580. It is to be noted that, in the wiring line 720, the via 722 may be omitted, and the wiring line 720 may be electrically coupled to the third die 300 (signal processing circuit) through the bonding wire 572.

In the present modification example, the first die 500 and the third die 300 are separately disposed. In such a case, it is possible to discharge heat generated in the laser chip 600 and heat generated in the detector 160 to outside through the wiring lines 710, 720, and 430 and the bonding wires 571 and 572. As a result, it is possible to suppress instability of operation caused by heat generation in the laser chip 600 and the detector 160.

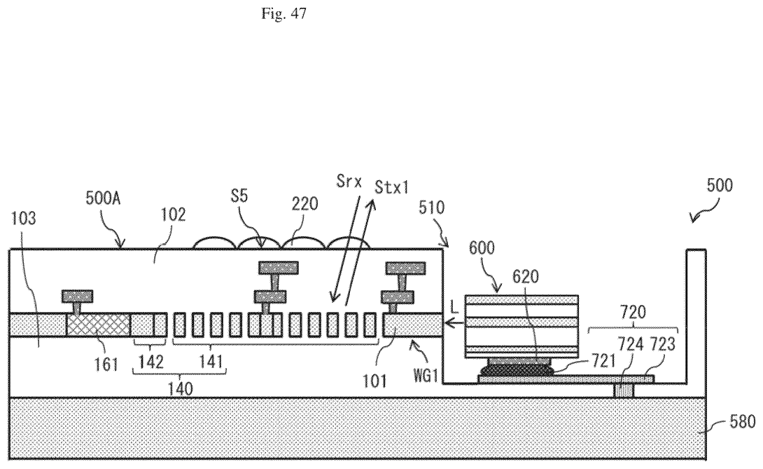

In the present modification example, for example, the wiring line 720 may be in contact with the support substrate 580 through a coupling wiring line 724 provided in an opening of the bottom surface of the recessed section 510, as illustrated in FIG. 47. In such a case, it is possible to efficiently discharge heat generated in the laser chip 600 to the support substrate 580 through the coupling wiring line 724. As a result, it is possible to suppress instability of operation caused by heat generation in the laser chip 600.

### Modification Example 4-6

FIG. 48 illustrates an exemplary planar configuration of the laser chip 600 and the recessed section 510 in the distance measuring device 2000 according to a modification example. FIG. 49 illustrates an exemplary cross-sectional configuration of the laser chip 600 and the recessed section 510 in the distance measuring device 2000 according to the modification example. In the second embodiment described above and the modification examples thereof, for example, a surface (side surface 510a) where light (laser light L) of the laser chip 600 enters of inner surfaces (side surfaces) of the recessed section 510 may be provided not right opposed but obliquely opposed to the light-emitting surface of the laser chip 600 in a plan view, as illustrated in FIG. 48. The side surface 510a is a surface, adjacent to the light-emitting surface of the laser chip 600, of the inner surfaces (side surfaces) of the recessed section 510. In addition, in the second embodiment described above and the modification examples thereof, for example, the surface (side surface 510a), adjacent to the light-emitting surface of the laser chip 600, of the inner surfaces (side surfaces) of the recessed section 510 may be provided not right opposed but obliquely opposed to the light-emitting surface of the laser chip 600 in a vertical cross-sectional view, as illustrated in FIG. 49.

In addition, in the second embodiment described above and the modification examples thereof, an insulating film 590 such as an antireflection film may cover the side surface 510a. The antireflection film prevents (or reduces) reflection of light from the laser chip 600. For example, a waveguide 602 that causes laser oscillation of the active layer 601 and the optical waveguide WG1 may be disposed on the same straight line, as illustrated in FIGS. 48 and 49. This makes it possible to prevent (or reduce) light reflected by the side surface 510a of the laser light L emitted from laser chip 600 from directly entering the active layer 601 as return light. As a result, it is possible to suppress instability of operation caused by the return light.

In the modification example, for example, the waveguide 602 and the optical waveguide WG1 may be disposed on a line segment parallel to a normal to the side surface 510a. Even in such a case, it is possible to prevent (or reduce) light reflected by the side surface 510a of the laser light L emitted from laser chip 600 from directly entering the active layer 601 as return light. As a result, it is possible to suppress instability of operation caused by the return light.

### Modification Example 4-7

FIG. 51 illustrates an exemplary cross-sectional configuration of the laser chip 600 and the recessed section 510 in the distance measuring device 2000 according to a modification example. In the second embodiment described above and the modification examples thereof, for example, a recessed section 591 may be provided on the bottom surface of the recessed section 510, as illustrated in FIG. 51. The recessed section 591 regulates the position of the laser chip 600. The recessed section 591 has a configuration that makes it possible to regulate positions of one or more protrusion sections 630 provided to the laser chip 600, and is, for example, a triangular groove or a mortar-shaped groove. Providing the recessed section 591 on the bottom surface of the recessed section 510 in such a manner makes it possible to regulate the position of the laser chip 600. As a result, it is possible to accurately dispose the laser chip 600 at a desired position, which makes it possible to suppress instability of operation caused by a decrease in then optical coupling property between the laser chip 600 and the optical waveguide WG1.

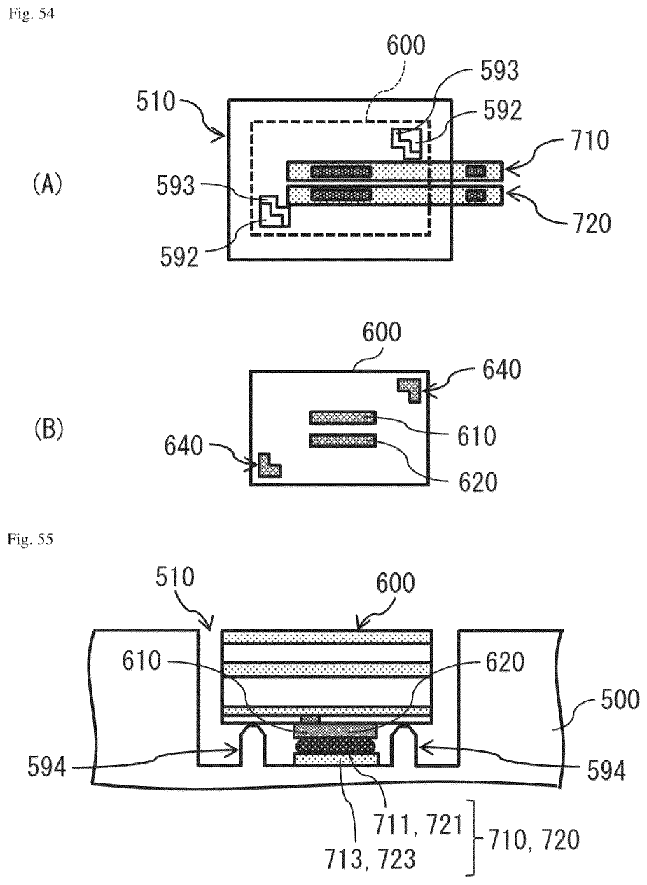

FIG. 52 illustrates an exemplary planar configuration of the laser chip 600 and the recessed section 510 in the distance measuring device 2000 according to a modification example. FIG. 53 illustrates an exemplary cross-sectional configuration taken a line A-A in FIG. 52. (A) of FIG. 54 illustrates an exemplary planar configuration of the recessed section 510 in a case where the laser chip 600 is removed in FIG. 52. (B) of FIG. 54 illustrates an exemplary planar configuration of a back surface of the laser chip 600.

In the present modification example, for example, a plurality of recessed sections 592 may be provided on the bottom surface of the recessed section 510, as illustrated in FIGS. 52, 53, and 54. The recessed sections 592 each regulate the position of the laser chip 600. Each of the recessed sections 592 is provided at a location opposed to one of four corners of the laser chip 600, and has, for example, a L-shape in a plan view. It is to be noted that FIGS. 52 and 54 exemplify a case where two recessed sections 592 are provided on the bottom surface of the recessed section 510.

In the present modification example, for example, a protrusion section 593 may be further provided at a position adjacent to the recessed section 592, as illustrated in FIGS. 52, 53, and 54. The protrusion section 593 regulates the height of the laser chip 600. The protrusion section 593 also serves as, for example, a sidewall of the recessed section 592, and has, for example, a W-shape in a plan view. It is to be noted that FIGS. 52 and 54 exemplify a case where two protrusion sections 593 are provided on the bottom surface of the recessed section 510.

In the present modification example, providing two recessed sections 592 on the bottom surface of the recessed section 510 makes it possible to regulate the position in a rotation direction of the laser chip 600 in a plan view. In addition, in the present modification example, providing the protrusion section 593 also serving as the sidewall of the recessed section 592 makes it possible to regulate the height of the laser chip 600. As a result, it is possible to accurately dispose the laser chip 600 at a desired position, which makes it possible to suppress instability of operation caused by a decrease in the optical coupling property between the laser chip 600 and the optical waveguide WG1.

### Modification Example 4-8

FIG. 55 illustrates a cross-sectional example of the laser chip 600 and the recessed section 510 in the distance measuring device 2000 according to a modification example. In the second embodiment described above and the modification examples thereof, for example, one or a plurality of protrusion sections 594 may be provided on the bottom surface of the recessed section 510, as illustrated in FIG. 55. The one or plurality of protrusion sections 594 regulates the height of the laser chip 600. The plurality of protrusion section 594 is disposed, for example, at positions adjacent to the wiring layers 713 and 723. As a result, it is possible to accurately dispose the laser chip 600 at a desired position, which makes it possible to suppress instability of operation caused by a decrease in the optical coupling property between the laser chip 600 and the optical waveguide WG1.

### Modification Example 4-9

FIG. 56 illustrates an exemplary cross-sectional configuration of the distance measuring device 2000 according to a modification example. In the second embodiment described above and modification examples thereof, for example, the PIC substrate 500A may include, for example, an optical waveguide WGa separately from the optical waveguide WG1, as illustrated in FIG. 56.

In the PIC substrate 500A, the optical waveguide WGa is provided, for example, in a layer (e.g., the BOX layer 103) different from a layer including the optical waveguide WG1. The optical waveguide WGa is provided in a layer 101a including a material having a refractive index equal to or larger than the refractive index (1.44) of SiO₂ and equal to or less than the refractive index (3.45) of Si. The optical waveguide WGa may be provided in the layer 101a including, for example, a material, such as Ta₂O₅, Nb₂O₂, ZnO, TeO₂, CeO₂, or Al₂O₃, having a refractive index equal to or larger than 2.0 and equal to or less than the refractive index (3.45) of Si. Providing the optical waveguide WGa in the layer 101a including such a material makes it possible to obtain the high-quality optical waveguide WGa having few defects.

The laser light L emitted from the laser chip 600 enters the optical waveguide WGa. A diffraction grating 501 is provided at a location, opposed to a diffraction grating 502 of the optical waveguide WG1 (a portion directly above the diffraction grating 502), of the optical waveguide WGa. The diffraction grating 501 is, for example, an element in which a plurality of grooves or through holes is disposed side by side in one line with a pitch of several hundreds of nm in the layer 101a. The diffraction grating 501 outputs the laser light L having propagated through the optical waveguide WGa toward the diffraction grating 502. The diffraction grating 502 is, for example, an element in which a plurality of grooves or through holes is disposed side by side in one line with a pitch of several hundreds of nm in the optical waveguide WG1. The diffraction grating 502 guides the laser light L outputted from the optical waveguide WGa into the optical waveguide WG1. The laser light L propagating through the optical waveguide WG1 is inputted to the modulator 110.

In the PIC substrate 500A, a reflection layer 503 may be provided at a location opposed to the diffraction grating 501 with the diffraction grating 502 interposed therebetween (that is, directly below the diffraction grating 501). The reflection layer 503 plays a role in reflecting light having passed through the diffraction grating 502 without being introduced into the diffraction grating 502 of the laser light L outputted from the diffraction grating 501 to return the light to the diffraction grating 502. The reflection layer 503 is provided, for example, in the interlayer insulating film 102. The reflection layer 503 includes a metal (e.g., Cu).

In the present modification example, in the PIC substrate 500A, the optical waveguide WGa is provided separately from the optical waveguide WG1. Accordingly, it is possible to select, as the material of the optical waveguide WGa, a material suitable for capturing the laser light L emitted from the laser chip 600. This makes it possible to obtain high-quality optical waveguide WGa having few defects, which makes it possible to suppress instability of operation caused by a crystal defect, as compared with a case where the laser light L is directly captured in the optical waveguide WG1.

### Modification Example 4-10

FIGS. 57 and 58 each illustrate an exemplary cross-sectional configuration of the distance measuring device 2000 according to a modification example. In the second embodiment described above and the modification examples thereof, in place of the recessed section 510, a cutout section 511 that accommodates the laser chip 600 may be provided in the PIC substrate 500A. Even in such a case, it is possible to achieve effects similar to those in the second embodiment described above and the modification examples thereof.

It is to be noted that the pad electrodes 303, 304, and 305, the wiring line 410, the vias 411 and 412, the wiring layer 413, the wiring line 420, the vias 421 and 422, the wiring layer 423, the wiring line 430, the vias 431 and 432, the wiring layer 433, the heat dissipation member 440, the via 441, the wiring layer 442, the electrodes 610 and 620, the wiring line 710, the via 712, the wiring layer 713, the wiring line 720, the via 722, the wiring layer 723, and the coupling wiring line 724 are not limited to the materials described above, and each may have, for example, a stacked structure including W, Al, Cu, Ag, or an alloy thereof, and a barrier metal (e.g., TiN, Ti, Ta, or TaN).

### 5. Application Example

The technology according to the present disclosure is applicable to various products. For example, the technology according to the present disclosure may be achieved in the form of a device to be mounted to a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

FIG. 59 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 59, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of op-erations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 59 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

FIG. 60 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 60 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by super-imposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 59, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an elec-tromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infras-tructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electro-magnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 59, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 59 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

It is to be noted that it is possible to mount a computer program for implementing each function of the distance measuring devices 1000 and 2000 described with reference to FIGS. 1 to 58 and the like on any control unit or the like. In addition, it is also possible to provide a computer-readable recording medium in which such a computer program is stored. The recording medium is, for example, a magnetic disk, an optical disk, a magneto-optical disk, a flash memory, or the like. In addition, the computer program described above may be distributed through a network, for example, without using a recording medium.

It is possible for the vehicle control system 7000 described above to use any of the distance measuring devices 1000 and 2000 described with reference to FIGS. 1 to 58 and the like, for example, as a light source steering section of an LIDAR as an environmental sensor.

In addition, at least some of components of the distance measuring devices 1000 and 2000 described with reference to FIGS. 1 to 58 and the like may be implemented in a module (e.g., an integrated circuit module included in one die) for the integrated control unit 7600 illustrated in FIG. 59. Alternatively, the distance measuring devices 1000 and 2000 described with reference to FIGS. 1 to 58 and the like may be implemented by a plurality of control units of the vehicle control system 7000 illustrated in FIG. 59.

Although the present disclosure has been described above with reference to the embodiments and the modification examples thereof, the present technology is not limited to the embodiments and the like described above, and may be modified in a variety of ways. It is to be noted that the effects described herein are merely illustrative. The effects of the present disclosure is not limited to the effects described herein. The present disclosure may have effects other than the effects described herein.

In addition, the present disclosure may have the following configurations.

(1) A distance measuring device, comprising:
a first section comprising a first optical waveguide configured to convey a chirp signal;
a light source that generates light for modulation by a modulator to generate the chirp signal;
a second section comprising logic circuitry that controls the light source, wherein the first section and the second section are stacked; and
a first conductor that forms at least part of an electrical connection between the logic circuitry and the light source, wherein the first conductor penetrates the first section at a position that is spaced apart from the light source in a first direction.

(2) The distance measuring device of (1), wherein the first conductor penetrates through the first section.

(3) The distance measuring device of one or more of (1) to (2), wherein the first conductor penetrates through at least part of the second section.

(4) The distance measuring device of one or more of (1) to (3), wherein the second section comprises a silicon layer and an interlayer insulating film.

(5) The distance measuring device of one or more of (1) to (4), wherein the first conductor penetrates through the interlayer insulating film to the silicon layer.

(6) The distance measuring device of one or more of (1) to (5), wherein the first conductor electrically connects to a wiring of the interlayer insulating film.

(7) The distance measuring device of one or more of (1) to (6), wherein the wiring is at a bonding surface between the first section and the second section.

(8) The distance measuring device of one or more of (1) to (7), wherein the wiring is between a first surface of the interlayer insulating film and a second surface of the interlayer insulating film opposite the first surface.

(9) The distance measuring device of one or more of (1) to (8), further comprising: at least one second conductor that electrically connects the first conductor to the light source.

(10) The distance measuring device of one or more of (1) to (9), wherein the first section includes at least part of the at least one second conductor.

(11) The distance measuring device of one or more of (1) to (10), wherein at least part of the at least one second conductor extends in the first direction.

(12) The distance measuring device of one or more of (1) to (11), wherein the at least one second conductor comprises a conductive bump.

(13) The distance measuring device of one or more of (1) to (12), further comprising: a third section that includes the light source, wherein the first section is between the second section and the third section.

(14) The distance measuring device of one or more of (1) to (13), wherein the third section includes at least part of the at least one second conductor.

(15) The distance measuring device of one or more of (1) to (14), wherein the first conductor penetrates through the third section, the first section, and at least part of the second section.

(16) A distance measuring device, comprising:
a first section comprising a first silicon layer, the first silicon layer comprising a first optical waveguide configured to convey an optical signal;
a light source that generates light for modulation by a modulator to generate the optical signal;
a second section comprising a second silicon layer, the second silicon layer comprising logic circuitry that controls the light source, wherein the first section and the second section are stacked; and
a first conductor that forms at least part of an electrical connection between the logic circuitry and the light source, wherein the first conductor penetrates the first section at a position that is spaced apart from the light source in a first direction.

(17) The distance measuring device of (16), wherein the light source is positioned between the first optical waveguide and the first conductor.

(18) The distance measuring device of (16) to (17), wherein the first section further comprises:
a splitter configured to split the optical signal into a transmission signal and a reference signal; and
a coupler and detector circuitry configured to output a beat signal based on the reference signal and a reflected signal.

(19) The distance measuring device of claims (16) to (18), wherein the logic circuitry comprises:
a controller configured to output an electronic control signal that controls generation of the optical signal.

(20) A distance measuring device, comprising:
a first section comprising a first optical waveguide configured to convey a chirp signal;
a light source that generates light for modulation by a modulator to generate the chirp signal;
a second section comprising logic circuitry that controls the light source, wherein the first section and the second section are stacked;
a first conductor that forms at least part of an electrical connection between the logic circuitry and the light source, wherein the first conductor penetrates the first section at a position that is spaced apart from the light source in a first direction; and
at least one second conductor that forms a remaining part of the electrical connection between the logic circuitry and the light source, wherein at least part of the at least one second conductor extends in the first direction.

### (B1)

A distance measuring device including:
a semiconductor substrate including a light source that outputs a light signal;
a photonic integration circuit substrate including a modulator, a first waveguide, a splitter, a second waveguide, and a signal generator that are provided in a common silicon layer, the modulator that generates a chirp signal by modulating a frequency of the light signal, the first waveguide that transmits the chirp signal, the splitter that splits the chirp signal into a transmission signal and a reference signal, the second waveguide that transmits a return signal corresponding to a signal having a delayed phase in relation with the transmission signal, and the signal generator that generates a beat signal on the basis of the reference signal and the return signal; and
a signal processing substrate including a converter, a signal processor, and a controller, the converter that performs analog-to-digital conversion of the beat signal, the signal processor that processes the beat signal being digital generated by the converter, and the controller that controls the light source, the modulator, and the signal generator, the photonic integration circuit substrate and the semiconductor substrate being stacked on the signal processing substrate in this order, and
the semiconductor substrate and the signal processing substrate being electrically coupled to each other through a via.

### (B2)

The distance measuring device according to (1), further including a first wiring line that electrically couples the light source and the controller to each other, in which the first wiring line includes a first via and a second via as the via, the first via being provided in the semiconductor substrate, and the second via being provided in the semiconductor substrate, the photonic integration circuit substrate, and the signal processing substrate.

### (B3)

The distance measuring device according to (1) or (2), further including a first heat dissipation member that is electrically coupled to the light source, in which the first heat dissipation member includes a third via and a first wiring layer, the third via being provided in the semiconductor substrate, and the first wiring layer being disposed on a front surface of the semiconductor substrate.

### (B4)

The distance measuring device according to any one of (1) to (3), in which the photonic integration circuit substrate includes a diffraction grating at a location opposed to the light source, the diffraction grating that guides the light signal outputted from the light source to the modulator.

### (B5)

The distance measuring device according to any one of (1) to (4), in which the photonic integration circuit substrate includes a second heat dissipation member at a location opposed to the light source.

### (B6)

A distance measuring device including:
a light source chip that outputs a light signal;
a photonic integration circuit substrate including a modulator, a first waveguide, a splitter, a second waveguide, and a signal generator that are provided in a common silicon layer, the modulator that generates a chirp signal by modulating a frequency of the light signal, the first waveguide that transmits the chirp signal, the splitter that splits the chirp signal into a transmission signal and a reference signal, the second waveguide that transmits a return signal corresponding to a signal having a delayed phase in relation with the transmission signal, and the signal generator that generates a beat signal on the basis of the reference signal and the return signal; and
a signal processing substrate including a converter, a signal processor, and a controller, the converter that performs analog-to-digital conversion of the beat signal, the signal processor that processes the beat signal being digital generated by the converter, and the controller that controls the light source chip, the modulator, and the signal generator, the photonic integration circuit substrate having a recessed section or a cutout section that accommodates the light source chip,
an end section of the first waveguide being exposed on an inner surface of the recessed section or the cutout section,
the light source chip being mounted in the recessed section or the cutout section to cause the light signal to enter the end section, exposed on the inner surface of the recessed section or the cutout section, of the first waveguide,
the photonic integration circuit substrate being stacked on the signal processing substrate, and
the light source chip and the signal processing substrate being electrically coupled to each other through a via.

### (B7)

The distance measuring device according to (6), further including a first wiring line that electrically couples the light source chip and the controller to each other, in which the first wiring line includes a first via as the via, the first via being provided in the photonic integration circuit substrate and the signal processing substrate.

### (B8)

The distance measuring device according to (6) or (7), in which the photonic integration circuit substrate has a groove section provided on a bottom surface of the recessed section or the cutout section, and the groove section is provided at least in a region between the first waveguide and the light source chip of the bottom surface of the recessed section or the cutout section in a plan view.

### (B9)

The distance measuring device according to (6) or (7), in which
the signal processing substrate includes a silicon substrate and an interlayer insulating film, the silicon substrate being provided with the converter, the signal processor, and
the controller, and the interlayer insulating film being provided on the silicon substrate, the photonic integration circuit substrate and the signal processing substrate have a groove section provided on a bottom surface of the recessed section or the cutout section, the groove section having a depth that penetrates through the interlayer insulating film from the bottom surface of the recessed section or the cutout section, and
the groove section is provided at least in a region between the first waveguide and the light source chip of the bottom surface of the recessed section or the cutout section in a plan view.

### (B10)

The distance measuring device according to (8), further including a resin member embedded in the recessed section or the cutout section and the groove section.

### (B11)

The distance measuring device according to (9), further including a resin member embedded in the recessed section or the cutout section and the groove section.

### (B12)

The distance measuring device according to any one of (6) to (11), in which a surface where the light signal enters of inner surfaces of the recessed section or the cutout section is provided not right opposed but obliquely opposed to a light exit surface of the light source chip.

### (B13)

The distance measuring device according to any one of (6) to (12), further including an antireflection film that covers a surface where the light signal enters of inner surfaces of the recessed section or the cutout section.

### (B14)

A distance measuring device including:
a light source chip that outputs a light signal;
a photonic integration circuit substrate including a modulator, a first waveguide, a splitter, a second waveguide, and a signal generator that are provided in a common silicon layer, the modulator that generates a chirp signal by modulating a frequency of the light signal, the first waveguide that transmits the chirp signal, the splitter that splits the chirp signal into a transmission signal and a reference signal, the second waveguide that transmits a return signal corresponding to a signal having a delayed phase in relation with the transmission signal, and the signal generator that generates a beat signal on the basis of the reference signal and the return signal; and
a signal processing substrate including a converter, a signal processor, and a controller, the converter that performs analog-to-digital conversion of the beat signal, the signal processor that processes the beat signal being digital generated by the converter, and
the controller that controls the light source chip, the modulator, and the signal generator,
the photonic integration circuit substrate having a recessed section or a cutout section that accommodates the light source chip,
an end section of the first waveguide being exposed on an inner surface of the recessed section or the cutout section,
the light source chip being mounted in the recessed section or the cutout section to cause the light signal to enter the end section, exposed on the inner surface of the recessed section or the cutout section, of the first waveguide,
the photonic integration circuit substrate being stacked on the signal processing substrate, and
the light source chip and the photonic integration circuit substrate being electrically coupled to each other by joining copper pads to each other, the copper pads being provided between the signal processing substrate and the photonic integration circuit substrate.

### (B15)

The distance measuring device according to (14), further including a second wiring line that electrically couples the light source chip and the controller to each other, in which
the second wiring line includes the copper pad and a coupling wiring layer that electrically couples the light source chip and the copper pads to each other.

It should be understood by those skilled in the art that various modifications, combinations, sub-combinations, and alterations may occur depending on design re-quirements and other factors insofar as they are within the scope of the appended claims or the equivalents thereof.

### REFERENCE SIGNS LIST

61 Si terrace section
62 p-type Si layer
63 island-shaped i-type Ge layer
64 two-dimensionally grown i-type Ge layer
65 n-type Ge layer
66 n-side electrode
67 p-side electrode
100 first die
100A PIC substrate
101 Si layer
101a layer
102 interlayer insulating film
103 BOX layer
104 Si substrate
105 diffraction grating
106 SOI substrate
107 heat dissipation member
110 modulator
120 splitter
130 circulator
140 antenna
141 Si antenna
142 heater
143, 144, 145 optical switch
150 coupler
151, 152 optical waveguide
160 detector
161, 162 Ge-PD
163 transimpedance amplifier
200 second die
201 semiconductor substrate
202 Si substrate
210 laser
211, 212 contact layer
220 lens
230 laser substrate
300 third die
301 Si substrate
302 interlayer insulating film
303, 304, 305 pad electrode
310 controller
320 DAC
330 ADC
340 FFT
410 wiring line
411, 412 via
413 wiring layer
420 wiring line
421, 422 via
423 wiring layer
430 wiring line
431, 432 via
433 wiring layer
440 heat dissipation member
441 via
442 wiring layer
500 first die
500A PIC substrate
501, 502 diffraction grating
503 reflection layer
510 recessed section
510a side surface
511 cutout section
520 groove section
530 resin member
540, 550 via hole
561, 562, 563 pad electrode
571, 572 bonding wire
580 support substrate
590 insulating film
591, 592 recessed section
593, 594 protrusion section
600 laser chip
601 active layer
602 waveguide
610, 620 electrode
630 protrusion section
710 wiring line
711 solder
712 via
713 wiring layer
720 wiring line
721 solder
722 via
723 wiring layer
724 coupling wiring line
1000, 2000 distance measuring device
H1 to H6 via hole
L laser light
S1, S2 joining surface
S3 entrance/exit surface
S4 joining surface
S5 entrance/exit surface
Sbt beat signal
Srx return signal
Stx, Stx1, Stx2 transmission signal
TG target
WG1, WG2, WG3, WGa optical waveguide

What is claimed is:

1. A distance measuring device, comprising:
a first section comprising a first optical waveguide configured to convey a chirp signal;
a light source that generates light for modulation by a modulator to generate the chirp signal;
a second section comprising logic circuitry that controls the light source, wherein the first section and the second section are stacked; and
a first conductor that forms at least part of an electrical connection between the logic circuitry and the light source, wherein the first conductor penetrates the first section at a position that is spaced apart from the light source in a first direction.

2. The distance measuring device of claim 1, wherein the first conductor penetrates through the first section.

3. The distance measuring device of claim 1, wherein the first conductor penetrates through at least part of the second section.

4. The distance measuring device of claim 3, wherein the second section comprises a silicon layer and an interlayer insulating film.

5. The distance measuring device of claim 4, wherein the first conductor penetrates through the interlayer insulating film to the silicon layer.

6. The distance measuring device of claim 4, wherein the first conductor electrically connects to a wiring of the interlayer insulating film.

7. The distance measuring device of claim 6, wherein the wiring is at a bonding surface between the first section and the second section.

8. The distance measuring device of claim 6, wherein the wiring is between a first surface of the interlayer insulating film and a second surface of the interlayer insulating film opposite the first surface.

9. The distance measuring device of claim 1, further comprising:
at least one second conductor that electrically connects the first conductor to the light source.

10. The distance measuring device of claim 9, wherein the first section includes at least part of the at least one second conductor.

11. The distance measuring device of claim 9, wherein at least part of the at least one second conductor extends in the first direction.

12. The distance measuring device of claim 9, wherein the at least one second conductor comprises a conductive bump.

13. The distance measuring device of claim 9, further comprising:
a third section that includes the light source, wherein the first section is between the second section and the third section.

14. The distance measuring device of claim 13, wherein the third section includes at least part of the at least one second conductor.

15. The distance measuring device of claim 13, wherein the first conductor penetrates through the third section, the first section, and at least part of the second section.

16. A distance measuring device, comprising:
a first section comprising a first silicon layer, the first silicon layer comprising a first optical waveguide configured to convey an optical signal;
a light source that generates light for modulation by a modulator to generate the optical signal;
a second section comprising a second silicon layer, the second silicon layer comprising logic circuitry that controls the light source, wherein the first section and the second section are stacked; and
a first conductor that forms at least part of an electrical connection between the logic circuitry and the light source, wherein the first conductor penetrates the first section at a position that is spaced apart from the light source in a first direction.

17. The distance measuring device of claim 16, wherein the light source is positioned between the first optical waveguide and the first conductor.

18. The distance measuring device of claim 16, wherein the first section further comprises:
a splitter configured to split the optical signal into a transmission signal and a reference signal; and
a coupler and detector circuitry configured to output a beat signal based on the reference signal and a reflected signal.

19. The distance measuring device of claim 18, wherein the logic circuitry comprises:
a controller configured to output an electronic control signal that controls generation of the optical signal.

20. A distance measuring device, comprising:
a first section comprising a first optical waveguide configured to convey a chirp signal;
a light source that generates light for modulation by a modulator to generate the chirp signal;
a second section comprising logic circuitry that controls the light source, wherein the first section and the second section are stacked;
a first conductor that forms at least part of an electrical connection between the logic circuitry and the light source, wherein the first conductor penetrates the first section at a position that is spaced apart from the light source in a first direction; and
at least one second conductor that forms a remaining part of the electrical connection between the logic circuitry and the light source, wherein at least part of the at least one second conductor extends in the first direction.
